(19) United States
(12) Patent Application Publication
(10) Pub. No.: US 2023/0397437 A1
(43) Pub. Date: Dec. 7, 2023

(54) SEMICONDUCTOR DEVICE AND ELECTRONIC DEVICE

(71) Applicant: SEMICONDUCTOR ENERGY LABORATORY CO., LTD., Atsugi-shi, Kanagawa-ken (JP)

(72) Inventors: Shunpei YAMAZAKI, Setagaya, Tokyo (JP); Takayuki IKEDA, Atsugi, Kanagawa (JP); Hitoshi KUNITAKE, Sehara, Kanagawa (JP); Tatsuya ONUKI, Atsugi, Kanagawa (JP)

(21) Appl. No.: 18/249,415

(22) PCT Filed: Oct. 8, 2021
(86) PCT No.: PCT/IB2021/059226

§ 371 Date: Apr. 18, 2023

(30) Foreign Application Priority Data
Oct. 21, 2020 (JP) 2020-177007
Oct. 21, 2020 (JP) 2020177007

(51) Int. Cl. H10B 53/30

(52) U.S. Cl. CPC H10B 53/30

(57) ABSTRACT

A semiconductor device that has a novel structure and includes a memory cell including a ferroelectric capacitor includes a first transistor (500A), a second transistor (500B), a first capacitor (600A), a second capacitor (600B), and a wiring (401). The first transistor is electrically connected to the first capacitor. The second transistor is electrically connected to the second capacitor. The wiring is positioned below the first transistor and the second transistor and is electrically connected to the first transistor or the second transistor. The first capacitor and the second capacitor each include a ferroelectric layer (630). The first capacitor and the second capacitor are placed on the same plane. The first capacitor and the second capacitor may include a region where they overlap with each other. Each of the first transistor and the second transistor preferably includes an oxide semiconductor in a channel. The ferroelectric layer preferably includes one or more selected from hafnium, zirconium, and Group III to IV elements.

### TECHNICAL FIELD

One embodiment of the present invention relates to a semiconductor device, a driving method of the semiconductor device, or the like. Another embodiment of the present invention relates to an electronic device including the semiconductor device.

Note that one embodiment of the present invention is not limited to the above technical field. Examples of the technical field of one embodiment of the present invention disclosed in this specification and the like include a semiconductor device, an imaging device, a display device, a light-emitting device, a power storage device, a memory device, a display system, an electronic device, a lighting device, an input device, an input/output device, a driving method thereof, and a manufacturing method thereof. Note that a semiconductor device refers to any device that utilizes semiconductor characteristics, and a memory device is a semiconductor device.

### BACKGROUND ART

In recent years, semiconductor devices have been developed, and LSI, CPUs, memories, and the like are mainly used as the semiconductor devices. A CPU is an assembly of semiconductor elements each including a chip of a semiconductor integrated circuit (including at least a transistor and a memory) processed from a semiconductor wafer and an electrode serving as a connection terminal.

A semiconductor circuit (IC chip) of an LSI, a CPU, a memory, or the like is mounted on a circuit board, for example, a printed wiring board, to be used as one of components of a variety of electronic devices.

A technique by which a transistor is formed using a semiconductor thin film formed over a substrate having an insulating surface has been attracting attention. The transistor is used in a wide range of electronic devices such as an integrated circuit (IC) and an image display device (also simply referred to as a display device). A silicon-based semiconductor material, an oxide semiconductor, and the like are known to be used for semiconductor thin films which can be used for transistors.

Memory cells using ferroelectrics have been actively researched and developed as shown in Non-Patent Document 1. In addition, active ongoing research on hafnium oxide for next-generation ferroelectric memories includes research on HfO₂-based materials with ferroelectricity (Non-Patent Document 2), research on ferroelectricity of hafnium oxide thin films (Non-Patent Document 3), ferroelectric properties of thin HfO₂ films (Non-Patent Document 4), and the like.

### REFERENCES

### Non-Patent Documents

[Non-Patent Document 1] T. S. Boescke, et al, “Ferroelectricity in hafnium oxide thin films”, APL99, 2011
[Non-Patent Document 2] Zhen Fan, et al, “Ferroelectric HfO₂-based materials for next-generation ferroelectric memories”, JOURNAL OF ADVANCED DIELECTRICS, Vol. 6, No. 2, 2016
[Non-Patent Document 3] Jun Okuno, et al, “SoC compatible 1T1C FeRAM memory array based on ferroelectric Hf0.5Zr0.5O2”, VLSI 2020
[Non-Patent Document 4] Akira Toriumi, “Ferroelectric properties of thin HfO2 films”, the Japan Society of Applied Physics, Vol. 88, No. 9, 2019

### SUMMARY OF THE INVENTION

### Problems to be Solved by the Invention

In a memory cell using a ferroelectric, the electrical characteristics of the ferroelectric are important. It is thus required to form a layer including a ferroelectric (a ferroelectric layer) with favorable electrical characteristics.

In a memory cell using a ferroelectric, data reading operation is performed depending on whether polarization inversion occurs in the ferroelectric. In that case, data retained in the memory cell is inverted along with the data reading operation. That is, the memory cell using a ferroelectric performs destructive reading. The memory cell using a ferroelectric, which performs destructive reading, needs data write-back operation each time data is read. The data write-back operation requires a high voltage to be applied to the ferroelectric, which might cause an increase in power consumption and the like.

An object of one embodiment of the present invention is to provide a novel semiconductor device and a driving method thereof. Another object of one embodiment of the present invention is to provide a semiconductor device capable of reading data without data destruction and a driving method thereof. Another object of one embodiment of the present invention is to provide a semiconductor device with low power consumption and a driving method thereof. Another object of one embodiment of the present invention is to provide a highly reliable semiconductor device and a driving method thereof. Note that the objects of one embodiment of the present invention are not limited to the objects listed above. The objects listed above do not preclude the existence of other objects. Note that the other objects are objects that are not described in this section and will be described below. The objects that are not described in this section are derived from the description of the specification, the drawings, and the like and can be extracted as appropriate from the description by those skilled in the art. Note that one embodiment of the present invention is to solve at least one of the objects listed above and/or the other objects.

### Means for Solving the Problems

One embodiment of the present invention is a semiconductor device including a first transistor, a second transistor, a first capacitor, a second capacitor, and a wiring. The first transistor is electrically connected to the first capacitor; the second transistor is electrically connected to the second capacitor; the wiring is positioned below the first transistor and the second transistor and is electrically connected to the first transistor or the second transistor; the first capacitor and the second capacitor each include a ferroelectric layer; and the first capacitor and the second capacitor are placed on the same plane.

One embodiment of the present invention is a semiconductor device including a first transistor, a second transistor, a first capacitor, a second capacitor, and a wiring. The first transistor is electrically connected to the first capacitor; the second transistor is electrically connected to the second capacitor; the wiring is positioned below the first transistor and the second transistor and is electrically connected to the first transistor or the second transistor; the first capacitor and the second capacitor each include a ferroelectric layer; and the first capacitor and the second capacitor include a region where they overlap with each other.

In the semiconductor device of one embodiment of the present invention, each of the first transistor and the second transistor preferably includes an oxide semiconductor in a channel.

In the semiconductor device of one embodiment of the present invention, the ferroelectric layer preferably includes one or more selected from hafnium, zirconium, and Group 13 to Group 15 elements.

One embodiment of the present invention is an electronic device including the above conductor device and a CPU.

Note that other embodiments of the present invention are shown in the description of the following embodiments and the drawings.

### Effect of the Invention

One embodiment of the present invention can provide a novel semiconductor device and a driving method thereof. One embodiment of the present invention can provide a semiconductor device capable of reading data without data destruction and a driving method thereof. One embodiment of the present invention can provide a semiconductor device with low power consumption and a driving method thereof. One embodiment of the present invention can provide a highly reliable semiconductor device and a driving method thereof.

Note that the effects of one embodiment of the present invention are not limited to the effects listed above. The effects listed above do not preclude the existence of other effects. Note that the other effects are effects that are not described in this section and will be described below. The effects that are not described in this section are derived from the description of the specification, the drawings, and the like and can be extracted as appropriate from the description by those skilled in the art. Note that one embodiment of the present invention has at least one of the effects listed above and/or the other effects. Accordingly, depending on the case, one embodiment of the present invention does not have the effects listed above in some cases.

### BRIEF DESCRIPTION OF THE DRAWINGS

FIG. 1A and FIG. 1B are diagrams each illustrating a structure example of a semiconductor device.

FIG. 2A and FIG. 2B are diagrams each illustrating a structure example of a semiconductor device.

FIG. 3A and FIG. 3B are diagrams each illustrating a structure example of a semiconductor device.

FIG. 4A, FIG. 4B, and FIG. 4C are diagrams each illustrating a structure example of a semiconductor device.

FIG. 5A and FIG. 5B are diagrams each illustrating a structure example of a semiconductor device.

FIG. 6 is a diagram illustrating a structure example of a semiconductor device.

FIG. 7A and FIG. 7B are diagrams each illustrating a structure example of a semiconductor device.

FIG. 8 is a timing chart of a semiconductor device.

FIG. 9 is a timing chart of a semiconductor device.

FIG. 10 is a diagram illustrating a structure example of a semiconductor device.

FIG. 11 is a timing chart of a semiconductor device.

FIG. 12 is a timing chart of a semiconductor device.

FIG. 13 is a diagram illustrating a structure example of a semiconductor device.

FIG. 14A and FIG. 14B are diagrams each illustrating a structure example of a semiconductor device.

FIG. 15A and FIG. 15B are diagrams each illustrating a structure example of a semiconductor device.

FIG. 16A is a diagram showing the classification of crystal structures, FIG. 16B is a diagram showing an XRD spectrum of crystalline IGZO, and FIG. 16C is a diagram showing a nanobeam electron diffraction pattern of the crystalline IGZO.

FIG. 17A is a perspective view illustrating an example of a semiconductor wafer. FIG. 17B is a perspective view illustrating an example of a chip. FIG. 17C and FIG. 17D are perspective views illustrating examples of electronic components.

FIG. 18A to FIG. 18J are diagrams illustrating examples of electronic devices.

FIG. 19A to FIG. 19E are diagrams illustrating examples of electronic devices.

FIG. 20A to FIG. 20C are diagrams illustrating examples of electronic devices.

### MODE FOR CARRYING OUT THE INVENTION

Hereinafter, embodiments will be described with reference to the drawings. Note that the embodiments can be implemented with many different modes, and it is readily understood by those skilled in the art that modes and details thereof can be changed in various ways without departing from the spirit and scope thereof. Thus, the present invention should not be construed as being limited to the following description of the embodiments.

In this specification and the like, ordinal numbers such as “first”, “second”, and “third” are used to avoid confusion among components. Thus, the ordinal numbers do not limit the number of components. Furthermore, the ordinal numbers do not limit the order of components. For example, a “first” component in one embodiment in this specification and the like can be referred to as a “second” component in other embodiments, or the scope of claims. For another example, a “first” component in one embodiment in this specification and the like can be omitted in other embodiments, or the scope of claims.

The same components, components having similar functions, components made of the same material, components formed at the same time, and the like in the drawings are sometimes denoted by the same reference numerals, and repeated description thereof is skipped in some cases.

In this specification and the like, a metal oxide is an oxide of metal in a broad sense. Metal oxides are classified into an oxide insulator, an oxide conductor (including a transparent oxide conductor), an oxide semiconductor (also simply referred to as an OS), and the like. For example, in the case where a metal oxide is used in an active layer of a transistor, the metal oxide is referred to as an oxide semiconductor in some cases. That is, when a metal oxide can form a channel formation region of a transistor that has at least one of an amplifying function, a rectifying function, and a switching function, the metal oxide can be referred to as a metal oxide semiconductor. In the case where an OS FET or an OS transistor is mentioned, it can also be referred to as a transistor including a metal oxide or an oxide semiconductor.

### Embodiment 1

In this embodiment, structure examples of a semiconductor device will be described. The structure of one embodiment of the present invention can achieve a semiconductor device including a ferroelectric layer with favorable electric characteristics. In addition, the design flexibility of the semiconductor device can be increased. The integration degree of the semiconductor device can also be increased by stacking elements included in memory cells.

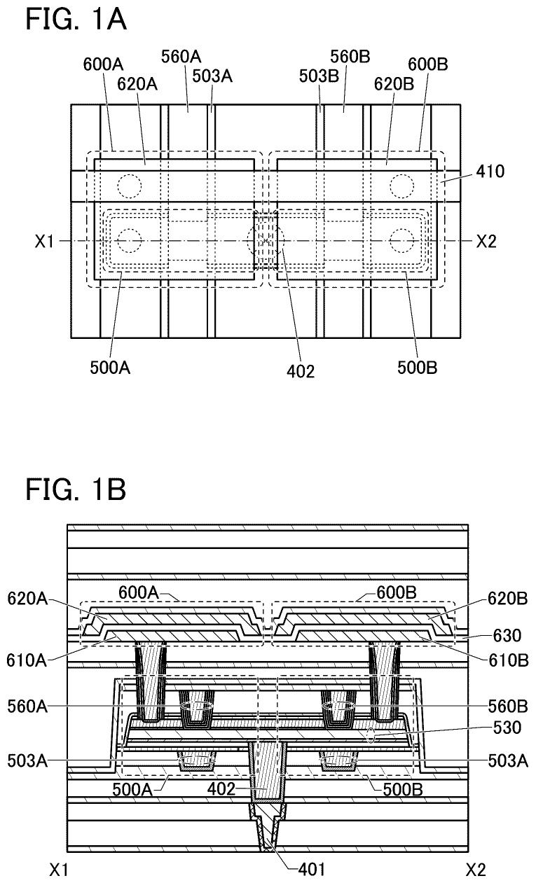

FIG. 1A is an example of a top view of a semiconductor device of one embodiment of the present invention, and FIG. 1B is an example of a schematic cross-sectional view along dashed-dotted line X1-X2 in FIG. 1A. The semiconductor device of one embodiment of the present invention illustrated in FIG. 1A and FIG. 1B includes, for example, a transistor 500A, a transistor 500B, a capacitor 600A, a capacitor 600B, and a wiring 401.

The transistor 500A is electrically connected to one electrode of the capacitor 600A. The transistor 500B is electrically connected to one electrode of the capacitor 600B. The wiring 401 is positioned below the transistor 500A and the transistor 500B and is electrically connected to the transistor 500A and the transistor 500B. The capacitor 600A and the capacitor 600B are each a capacitor including a ferroelectric layer. Note that a wiring 410 illustrated in FIG. 1A is a wiring connected to the other electrode of the capacitor 600A and the other electrode of the capacitor 600B. The wiring 410 is also referred to as a plate line. Reference numerals 503A and 503B illustrated in FIG. 1A and FIG. 1B denote wirings each functioning as a back gate electrode of the transistor 500A or the transistor 500B. Reference numerals 560A and 560B illustrated in FIG. 1A and FIG. 1B denote wirings each functioning as a gate electrode of the transistor 500A or the transistor 500B.

One memory cell is constituted by the transistor A and the capacitor 600A and one memory cell is constituted by the transistor B and the capacitor 600B. The wiring 401 functioning as a bit line is shared by these memory cells, so that the memory density can be increased.

The wiring 401 can be provided, for example, above a transistor including silicon in a channel formation region (Si transistor). The wiring 401 is electrically connected to the transistor provided therebelow. The wiring 401 is also electrically connected to the transistors 500A and 500B through a conductor 402. The conductor 402 is shared by electrodes for electrically connecting the wiring 401 to the transistors 500A and 500B, so that the memory density can be increased.

The wiring 401 functioning as a bit line receives a signal for driving the memory cell including the transistor 500A and the capacitor 600A (or the transistor 500B and the capacitor 600B). When a bit line driver circuit or the like is formed with Si transistors and is provided below the wiring 401, a wiring connecting the bit line and the bit line driver circuit can be shortened.

In addition, when the wiring 401 is provided below the transistors 500A and 500B, the area where the capacitors 600A and 600B are provided can be increased. A larger area where the capacitors 600A and 600B are provided allows the ferroelectric layer to be provided on a surface with higher planarity.

The transistors 500A and 500B are transistors each including a metal oxide in a channel formation region (OS transistors). The transistors 500A and 500B have characteristics of a low off-state current and the field-effect mobility that hardly changes even at high temperatures. The use of the transistors 500A and 500B achieves a semiconductor device with operation capability that hardly decreases even at high temperatures.

The transistors 500A and 500B can be provided above the wiring 401. The capacitors 600A and 600B are provided above the transistors 500A and 500B. The transistors 500A and 500B can be stacked over an insulating layer by using OS transistors as the transistors 500A and 500B.

An oxide 530 functioning as a semiconductor included in the transistors 500A and 500B preferably has a band gap of 2 eV or more, further preferably 2.5 eV or more. With the use of a metal oxide having such a wide band gap, the off-state current of the transistor can be reduced.

As the oxide 530, for example, a metal oxide such as an In-M-Zn oxide containing indium, the element M, and zinc (the element M is one or more kinds selected from aluminum, gallium, yttrium, tin, copper, vanadium, beryllium, boron, titanium, iron, nickel, germanium, zirconium, molybdenum, lanthanum, cerium, neodymium, hafnium, tantalum, tungsten, magnesium, and the like) can be used. Alternatively, an In—Ga oxide, an In—Zn oxide, or an indium oxide may be used as the oxide 530.

A structure in which OS transistors are used as the transistors 500A and 500B can offer a semiconductor device with few variations in transistor characteristics. In addition, a semiconductor device with favorable reliability can be provided. A semiconductor device with favorable electrical characteristics can also be provided.

The capacitor 600A and the capacitor 600B include a ferroelectric layer 630 between electrodes 610A and 620A (or electrodes 610B and 620B). The capacitor 600A and the capacitor 600B including the ferroelectric layer 630 are also referred to as ferroelectric capacitors.

In the structure of one embodiment of the present invention, the capacitor 600A and the capacitor 600B can be placed in a layer different from the wiring 401 functioning as a bit line and the capacitor 600A and the capacitor 600B can be placed on the same plane. This structure can increase the area of a surface where the ferroelectric layer is provided. As a result, a layer having a ferroelectric (ferroelectric layer) with favorable electrical characteristics can be formed. It is possible to obtain, for example, a memory cell including the capacitor 600A and the capacitor 600B in each of which the polarization (Pr) of the ferroelectric layer is increased.

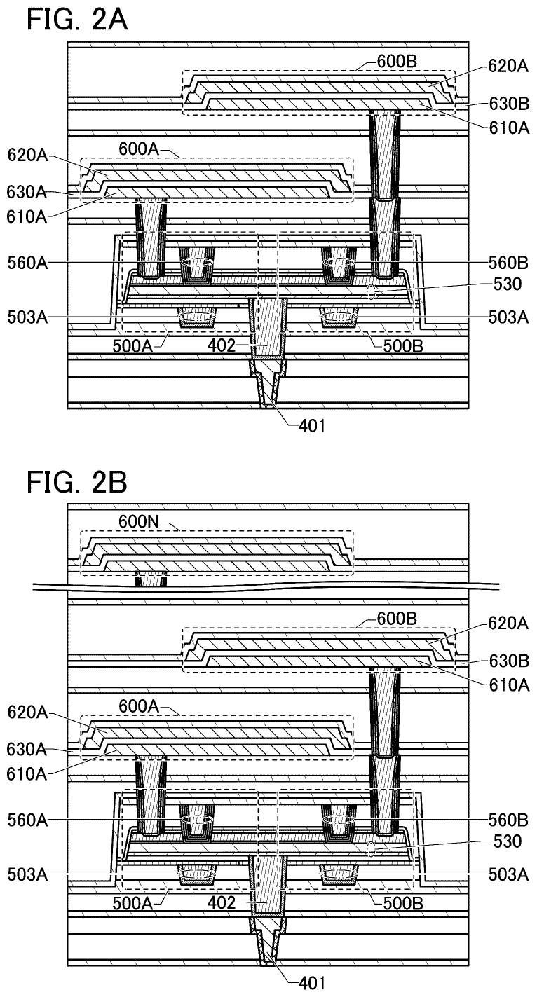

Although FIG. 1A and FIG. 1B illustrate the structure in which the capacitors 600A and 600B are provided over the same insulating layer, another structure may be used. For example, a ferroelectric layer 630A included in the capacitor 600A and a ferroelectric layer 630B included in the capacitor 600B can be placed in different layers as illustrated in FIG. 2A, which can further increase the area where the capacitors 600A and 600B are provided. FIG. 2A illustrates the structure in which the ferroelectric layers are placed in different two layers; however, one embodiment of the present invention is not limited thereto and the ferroelectric layers may be placed in different three to ten layers and a capacitor (a capacitor 600N in FIG. 2B) may be provided as illustrated in FIG. 2B, which can further increase the area of the capacitor.

In the structure of one embodiment of the present invention, as illustrated in FIG. 2A and FIG. 2B, the capacitor 600A and the capacitor 600B can be placed in a layer different from the wiring 401 functioning as a bit line and the capacitor 600A and the capacitor 600B can be placed in regions overlapping with each other. This structure can further increase the area of a surface where the ferroelectric layer is provided. As a result, a layer having a ferroelectric (ferroelectric layer) with favorable electrical characteristics can be formed. It is possible to obtain, for example, a memory cell including the capacitor 600A and the capacitor 600B in each of which the polarization (Pr) of the ferroelectric layer is increased. Note that this memory cell may be referred to as a universal memory.

When an OS transistor is used as the transistor in one embodiment of the present invention and is combined with a capacitor including a ferroelectric layer, elements included in a memory cell, such as the transistor and the capacitor, can be stacked. The structure in which the transistor and the capacitor are stacked can increase the area of a surface where the ferroelectric layer is provided as shown in FIG. 1A, FIG. 1B, FIG. 2A, and FIG. 2B. As a result, a layer having a ferroelectric (ferroelectric layer) with favorable electrical characteristics can be formed.

Examples of a material that can have ferroelectricity and can be used for the ferroelectric layer 630 include hafnium oxide, zirconium oxide, and cerium oxide. Examples of the material that can have ferroelectricity also include a material in which an element J1 (the element J1 here is zirconium (Zr), silicon (Si), aluminum (Al), gadolinium (Gd), yttrium (Y), lanthanum (La), strontium (Sr), or the like) is added to hafnium oxide, and a material in which an element J2 (the element J2 here is hafnium (Hf), silicon (Si), aluminum (Al), gadolinium (Gd), yttrium (Y), lanthanum (La), strontium (Sr), or the like) is added to zirconium oxide. It is preferable to use, for example, hafnium zirconium oxide (HfZrO_{X}: X is a real number greater than 0) in which zirconium is added to hafnium oxide.

As the material that can have ferroelectricity, a piezoelectric ceramic having a perovskite structure, such as lead titanate, barium strontium titanate (BST), strontium titanate, lead zirconate titanate (PZT), strontium bismuth tantalate (SBT), bismuth ferrite (BFO), or barium titanate, may be used. For example, the material that can have ferroelectricity can be a plurality of materials selected from the above-listed materials or can have a stacked-layer structure of a plurality of materials selected from the above-listed materials. Note that hafnium oxide, zirconium oxide, HfZrO_{X}, a material in which the element J1 is added to hafnium oxide, or the like may change its crystal structure (characteristics) according to processes and the like as well as deposition conditions; thus, in this specification and the like, a material that exhibits ferroelectricity is referred to not only as a ferroelectric but also as a material that can have ferroelectricity or a material that has ferroelectricity.

Examples of the material that can have ferroelectricity also include scandium aluminum nitride (Al₁₋ₐScₐN_{b} (a is a real number greater than 0 and less than 0.5, and b is 1 or an approximate value thereof)), an Al—Ga—Sc nitride, and a Ga—Sc nitride. Examples of the material that can have ferroelectricity also include a metal nitride containing an element M1, an element M2, and nitrogen. Here, the element M1 is one or more selected from aluminum (Al), gallium (Ga), indium (In), and the like. The element M2 is one or more selected from boron (B), scandium (Sc), yttrium (Y), lanthanum (La), cerium (Ce), neodymium (Nd), europium (Eu), titanium (Ti), zirconium (Zr), hafnium (Hf), vanadium (V), niobium (Nb), tantalum (Ta), chromium (Cr), and the like. Note that the atomic ratio of the element M1 to the element M2 can be set as appropriate. A metal oxide containing the element M1 and nitrogen has ferroelectricity in some cases even though the metal oxide does not contain the element M2. Examples of the material that can have ferroelectricity also include a material in which an element M3 is added to the above metal nitride. Note that the element M3 is one or more selected from magnesium (Mg), calcium (Ca), strontium (Sr), zinc (Zn), cadmium (Cd), and the like. Here, the atomic ratio of the element M1 to the element M2 and the element M3 can be set as appropriate. Since the above metal nitride contains at least a Group 13 element and nitrogen, which is a Group 15 element, the metal nitride is referred to as a ferroelectric belonging to Group 13 to Group 15, a ferroelectric of a Group 13 nitride, or the like in some cases.

Among the materials used for the ferroelectric layer, HfZrO_{X} is preferable because the material can have ferroelectricity even when being processed into a thin film of several nanometers. Here, the thickness of the ferroelectric layer can be less than or equal to 100 nm, preferably less than or equal to 50 nm, further preferably less than or equal to 20 nm, and still further preferably less than or equal to 10 nm (typically, greater than or equal to 2 nm and less than or equal to 9 nm). The ferroelectric layer that can have a small thickness can be combined with a miniaturized transistor to fabricate a semiconductor device.

In the case where HfZrO_{X} is used as the material that can have ferroelectricity, deposition is preferably performed by an atomic layer deposition (ALD) method, particularly a thermal ALD method. In the case where the material that can have ferroelectricity is deposited by a thermal ALD method, it is suitable to use a material that does not contain a hydrocarbon (also referred to as Hydro Carbon or HC) for a precursor. When the material that can have ferroelectricity contains one or both of hydrogen and carbon, crystallization of the material that can have ferroelectricity might be hindered. Thus, the precursor that does not contain a hydrocarbon is preferably used as described above to reduce the concentration(s) of one or both of hydrogen and carbon in the material that can have ferroelectricity. Examples of the precursor that does not contain a hydrocarbon include a chlorine-based material. In the case where a material containing hafnium oxide and zirconium oxide (HfZrO_{X}) is used as the material that can have ferroelectricity, HfCl₄ and/or ZrCl₄ are/is used as the precursor.

In the case of depositing a film of the material that can have ferroelectricity, impurities in the film, at least one or more of hydrogen, a hydrocarbon, and carbon here, are thoroughly removed, whereby a highly purified intrinsic film having ferroelectricity can be formed. Note that the highly purified intrinsic film having ferroelectricity and a highly purified intrinsic oxide semiconductor described in a later embodiment are highly compatible with each other in the manufacturing process. Thus, a method for manufacturing a semiconductor device with high productivity can be provided.

In the case where HfZrO_{X} is used as the material that can have ferroelectricity, hafnium oxide and zirconium oxide are preferably deposited alternately by a thermal ALD method to have a composition of 1:1.

In the case where the material that can have ferroelectricity is deposited by a thermal ALD method, H₂O or O₃ can be used as an oxidizer. However, the oxidizer in the thermal ALD method is not limited thereto. For example, the oxidizer in the thermal ALD method may contain any one or more selected from O₂, O₃, N₂O, NO₂, H₂O, and H₂O₂.

The crystal structure of the material that can have ferroelectricity is not particularly limited. For example, the material that can have ferroelectricity may have any one or more selected from cubic, tetragonal, orthorhombic, and monoclinic crystal structures. In particular, the material that can have ferroelectricity preferably has an orthorhombic crystal structure to exhibit ferroelectricity. Alternatively, the material that can have ferroelectricity may have a composite structure of an amorphous structure and a crystal structure.

A base film (e.g., a conductor) of the ferroelectric layer preferably has a top surface with high planarity. For example, the top surface of the base conductor can have an arithmetic average roughness (Ra) or a root-mean-square (RMS) roughness of 2 nm or less, preferably 1 nm or less, further preferably 0.8 nm or less, still further preferably 0.5 nm or less, and yet further preferably 0.4 nm or less. Such high planarity of the top surface of the conductor can improve the crystallinity of the ferroelectric layer to increase the ferroelectricity.

In the case where the ferroelectric layer includes a layered crystal, a layer for improving the crystallinity may be formed in an upper portion and/or a lower portion of the ferroelectric layer. The layer for improving the crystallinity is preferably, for example, a layer that contains at least one of the elements included in the ferroelectric layer. The composition of the layer for improving the crystallinity is preferably different from that of the ferroelectric layer. For example, in the case where HfZrO_{X} is used for the ferroelectric layer, specifically, a metal oxide such as hafnium oxide or zirconium oxide, hafnium, or zirconium is preferably used for the layer for improving the crystallinity.

The composition of the layer for improving the crystallinity does not necessarily include the elements included in the ferroelectric layer. In that case, silicon, yttrium, aluminum, scandium, or the like can be used as the element. By providing the layer for improving the crystallinity, the crystallinity of the ferroelectric layer can be improved to increase the ferroelectricity. Since an improvement in the crystallinity of the ferroelectric layer can increase the ferroelectricity, the layer for improving the crystallinity can be referred to as a layer that increases the remnant polarization of the ferroelectric layer.

When the structure described in this embodiment is employed for the semiconductor device using the transistor including an oxide semiconductor and the capacitor including a ferroelectric layer, miniaturization or high integration can be achieved.

Note that this embodiment can be combined with any of the other embodiments described in this specification as appropriate.

### Embodiment 2

Described in this embodiment is a driving method of the semiconductor device including the memory cell described in Embodiment 1.

One embodiment of the present invention relates to a semiconductor device including a memory cell. A semiconductor device including a memory cell can be referred to as a memory device. The memory cell has a function of retaining data. Specifically, the memory cell includes a capacitor. The capacitor includes a ferroelectric layer between a first electrode and a second electrode. The capacitor including the ferroelectric layer is sometimes referred to as a ferroelectric capacitor.

In the ferroelectric capacitor, when a voltage (electric field) is applied between the electrodes, the polarization direction and the polarization amount of the ferroelectric layer change in accordance with the direction and the amount of the applied voltage. In the memory cell including the ferroelectric capacitor, a signal (data) is stored (written) by utilizing the change in the polarization state of the ferroelectric layer. Even when the voltage between the electrodes is made zero, polarization remains (remnant polarization) in the ferroelectric layer of the ferroelectric capacitor. A voltage for inverting the polarization (polarization inversion) is applied to rewrite the polarization (such a voltage is also referred to as polarization inversion voltage).

When a voltage that exceeds the polarization inversion voltage is applied to the ferroelectric capacitor in data reading from the memory cell, the polarization state of the ferroelectric layer (the polarization direction of the remnant polarization) changes, which requires an operation for returning the polarization state to the original state. That is, data refresh is required when data is read from the ferroelectric capacitor by applying a voltage that exceeds the polarization inversion voltage to the ferroelectric capacitor. In other words, a data reading operation from the memory cell is performed by destructive reading in the case where data is read by applying a voltage that exceeds the polarization inversion voltage to the ferroelectric capacitor.

One embodiment of the present invention is a driving method of a semiconductor device in which data can be read from a memory cell including a ferroelectric capacitor without performing destructive reading.

Specifically, when the reading operation is performed in the memory cell including the ferroelectric capacitor, a voltage applied to the counter electrode of the ferroelectric capacitor is gradually increased so as not to cause polarization destruction in the ferroelectric capacitor. A data reading operation from the memory cell is performed by applying a voltage that does not cause polarization inversion of the ferroelectric layer to the ferroelectric capacitor. In a subsequent data reading operation from the memory cell of this driving method, a voltage higher than that applied in the previous reading operation is applied to the ferroelectric capacitor as a voltage that does not cause polarization inversion of the ferroelectric layer.

In one embodiment of the present invention, a voltage that does not exceed the polarization inversion voltage is applied to the ferroelectric capacitor in the data reading operation, so that the polarization direction of the remnant polarization in the ferroelectric layer can be maintained before and after the data reading. Thus, the semiconductor device of one embodiment of the present invention can retain data for a long time. Accordingly, the frequency of refresh (data rewriting to the memory cell) can be reduced, leading to a reduction in power consumption of the semiconductor device of one embodiment of the present invention. A ferroelectric capacitor in which a ferroelectric layer is provided between electrodes can retain data for a long time without a structure for increasing capacity, e.g., a trench structure. Accordingly, a semiconductor device which is easily fabricated can be obtained.

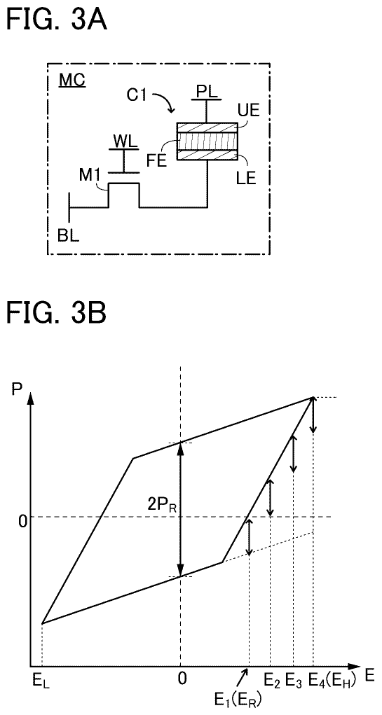

FIG. 3A is a circuit diagram of a memory cell MC including a ferroelectric capacitor. Note that the memory cell MC is also referred to as a cell. The memory cell MC includes a transistor M1 and a ferroelectric capacitor C1.

The ferroelectric capacitor C1 is schematically illustrated as a capacitor including a ferroelectric layer FE between an electrode UE and an electrode LE. The reading operation of the memory cell MC is performed, for example, as follows: a wiring BL (also referred to as a bit line) connected to the transistor M1 is set to a predetermined potential to be brought into an electrically floating state; the transistor M1 is brought into a conduction (on) state by the control of a wiring WL (also referred to as a word line); and a voltage of a wiring PL (also referred to as a plate line) on the electrode UE side is changed. Then, capacitive coupling of the ferroelectric capacitor changes the potential of the wiring BL. This change in the potential of the wiring BL depends on the polarization state of the ferroelectric layer of the ferroelectric capacitor; thus, a potential corresponding to written data can be read to the wiring BL.

FIG. 3B is a graph showing a polarization magnitude (polarization amount) corresponding to electric fields applied to the ferroelectric layer FE. Note that, for easy understanding, change in polarization corresponding to the electric field of the ferroelectric layer FE is indicated by a straight line in FIG. 3B, however, measurement data should be represented by a curve. The horizontal axis in FIG. 3B represents an electric field E applied to the ferroelectric layer. The vertical axis represents polarization P of the ferroelectric layer. A difference between the positive polarization and the negative polarization at an electric field of 0 is indicated by 2P_{R}.

The polarization in the ferroelectric layer increases as the electric field applied to the ferroelectric layer FE increased. When the electric field applied to the ferroelectric layer is decreased after an electric field EH is applied to the ferroelectric layer, positive electric charges are pulled to one electrode side of the capacitor and negative electric charges are pulled to the other electrode side of the capacitor; thus, positive polarization remains when the electric field becomes 0. The polarization in the ferroelectric layer decreases as the electric field applied to the ferroelectric layer FE decreases. When the electric field applied to the ferroelectric layer is increased after an electric field EL is applied to the ferroelectric layer, positive electric charges are pulled to the other electrode side of the capacitor C1 and negative electric charges are pulled to the one electrode side of the capacitor; thus, negative polarization remains when the electric field becomes 0. Voltages for applying the electric field EH and the electric field EL to the ferroelectric layer FE can be referred to as a polarization inversion voltage. When the polarization inversion voltage is applied to the ferroelectric capacitor C1, data can be written to the memory cell MC.

When a voltage that exceeds the polarization inversion voltage is applied to the capacitor C1 in data reading form the memory cell MC, the polarization state of the ferroelectric layer FE (the polarization direction of the remnant polarization) changes, which requires an operation for returning the polarization state to the original state. That is, data refresh is required when data is read from the memory cell MC by applying a voltage that exceeds the polarization inversion voltage to the capacitor C1.

In one embodiment of the present invention, a voltage that does not exceed the polarization inversion voltage is applied to the ferroelectric capacitor C1 when data is read from the memory cell MC, so that the polarization direction of the remnant polarization in the ferroelectric layer FE can be maintained. Specifically, when data is read from the memory cell MC, the electric field is gradually increased such that the polarization direction of the remnant polarization in the ferroelectric layer FE is maintained. More specifically, electric fields E₁ to E₄ that do not exceed the electric field EH indicated in FIG. 3B as an example are applied in order at each reading operation. A voltage for applying the electric fields E₁ to E₄ to the ferroelectric layer FE can be referred to as a voltage that does not cause polarization inversion. In one embodiment of the present invention, data can be read from the memory cell MC without performing so called destructive reading.

Note that in the case where the polarization direction of the remnant polarization in the ferroelectric layer FE is inverted by repeated reading operation from the ferroelectric capacitor, it is preferable to perform data refresh, an operation for rewriting data.

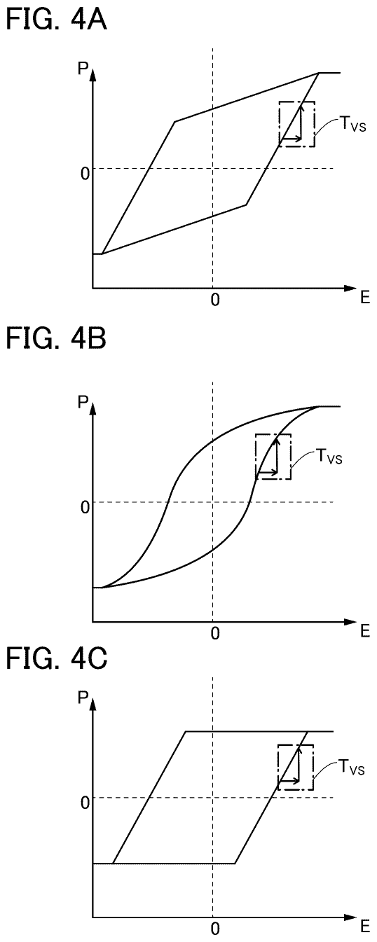

In the above-described reading operation of one embodiment of the present invention, when different electric fields are applied, polarization magnitude of each electric field preferably differs in a graph shown in FIG. 3B indicating the polarization magnitude (polarization amount) corresponding to the electric fields applied to the ferroelectric layer FE. Furthermore, in the reading operation of one embodiment of the present invention, when different electric fields are applied, the amount of change in each polarization preferably allows data reading in the graph shown in FIG. 3B indicating the polarization magnitude (polarization amount) corresponding to the electric fields applied to the ferroelectric layer FE. For example, as shown in FIG. 4A, T_{VS} (slope), a degree of change in polarization with respect to change in electric field, preferably has a positive slope in the shape of the graph indicating the polarization magnitude (polarization amount) corresponding to the electric fields applied to the ferroelectric layer FE. In addition, it is preferable that the amount of change in polarization not be greater than that in electric field. This structure enables small degree of change in remnant polarization at each reading operation in the case of performing the operation not for completely inverting the polarization direction of the remnant polarization in the ferroelectric layer FE but for partially inverting the polarization direction.

Note that an actual graph on the electric fields and the polarization in the ferroelectric layer changes in a curved shape as shown in FIG. 4B. In this case, the slope of the tangent can be regarded as the above-described slope, T_{VS}. Note that, this also applies to the shape of a graph shown in FIG. 4C.

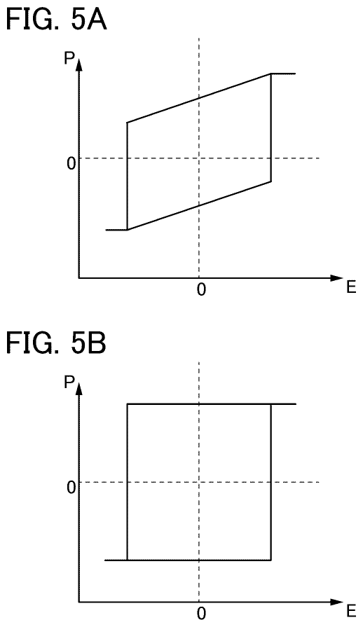

On the other hand, in the reading operation of one embodiment of the present invention, the shape of a graph shown in FIG. 5A indicating a polarization magnitude corresponding to electric fields is not preferable because a degree of change (slope) in polarization with respect to change in electric field has a positive slope and the amount of change in polarization is greater than that in electric field, leading to a steep slope. In these cases, the degree of change in polarization with respect to change in electric field is great, so that it becomes difficult to perform an operation for partially inverting the polarization direction of the remnant polarization in the ferroelectric layer FE. The description of FIG. 5A can apply to the shape of a graph shown in FIG. 5B.

### Structure Example of Semiconductor Device

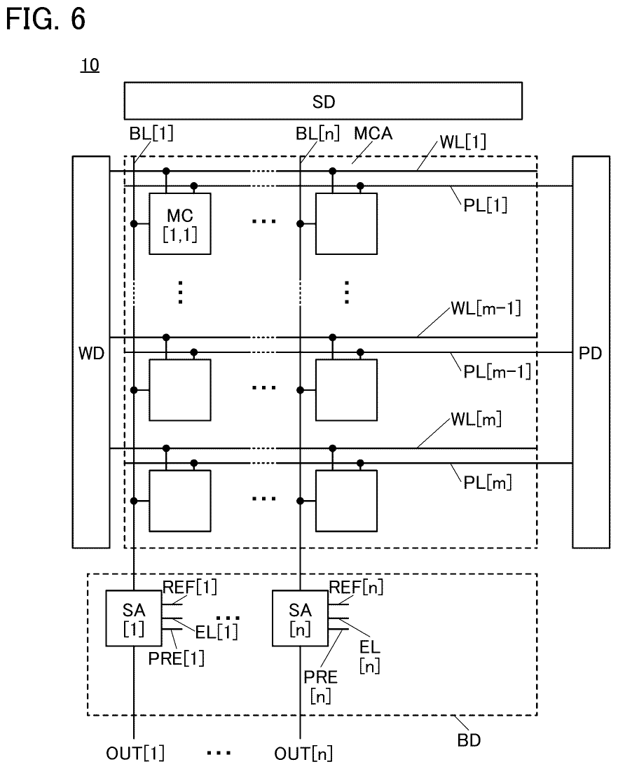

FIG. 6 is a block diagram illustrating a structure example of a semiconductor device 10 that is the semiconductor device of one embodiment of the present invention. The semiconductor device 10 can be a memory device, for example.

The semiconductor device 10 is provided with a memory cell array MCA in which memory cells MC are arranged in a matrix of m rows and n columns (m and n are each an integer greater than or equal to 1). The semiconductor device 10 includes a word line driver circuit WD, a plate line driver circuit PD, a potential generation circuit SD, and a bit line driver circuit BD.

The word line driver circuit WD is electrically connected to the memory cells MC through the wirings WL and electrically connected to the memory cells MC through wirings RWL. The plate line driver circuit PD is electrically connected to the memory cells MC through the wirings PL. The bit line driver circuit BD is electrically connected to the memory cells MC through the wirings BL.

Here, the memory cells MC in the same row can be electrically connected to the word line driver circuit WD through the same wiring WL and electrically connected to the plate line driver circuit PD through the same wiring PL. In addition, the memory cells MC in the same column can be electrically connected to the bit line driver circuit BD through the same wiring BL.

In this specification and the like, for example, a memory cell MC in the first row and the first column is denoted as a memory cell MC[1, 1] and a memory cell MC in the m-th row and the n-th column is denoted as a memory cell MC[m, n]. Furthermore, for example, a wiring WL and a wiring PL electrically connected to memory cells MC in the first row are denoted as a wiring WL[1] and a wiring PL[1], respectively, and a wiring WL and a wiring PL electrically connected to memory cells MC in the m-th row are denoted as a wiring WL[m] and a wiring PL[m], respectively. Moreover, for example, a wiring BL electrically connected to memory cells MC in the first column is denoted as a wiring BL[1], and a wiring BL electrically connected to memory cells MC in the n-th column is denoted as a wiring BL[n]. Note that the same applies to other components in some cases.

The word line driver circuit WD has a function of controlling the potential of the wiring WL. Specifically, the word line driver circuit WD has a function of selecting the memory cell MC to which data is written by controlling the potential of the wiring WL.

The plate line driver circuit PD has a function of controlling the potential of the wiring PL.

The bit line driver circuit BD has a function of generating data to be written to the memory cells MC and supplying the data to the memory cells MC in a predetermined column. In addition, the bit line driver circuit BD has a function of reading data written to the memory cells MC and outputting the data.

Details of the bit line driver circuit BD are described. The bit line driver circuit BD includes a sense amplifier circuit SA[1] to a sense amplifier circuit SA[n]. The sense amplifier circuit SA is electrically connected to the wiring BL, a wiring REF, a wiring EL, and a wiring PRE. Furthermore, the sense amplifier circuit SA[1] to the sense amplifier circuit SA[n] are electrically connected to a wiring OUT[1] to a wiring OUT[n].

The sense amplifier circuit SA has a function of amplifying a difference between the potential of the wiring BL and the potential of the wiring REF. For example, when the potential of the wiring BL is higher than that of the wiring REF, the sense amplifier circuit SA can output a high potential. On the other hand, when the potential of the wiring BL is lower than that of the wiring REF, the sense amplifier circuit SA can output a low potential. Thus, the bit line driver circuit BD can write binary data, specifically, binary digital data, to the memory cells MC and read the binary data written to the memory cells MC. For example, when the potential of the wiring BL is higher than that of the wiring REF, data “0” can be written to or read from the memory cells MC. On the other hand, when the potential of the wiring BL is lower than that of the wiring REF, data “1” can be written to or read from the memory cells MC.

The wiring EL can be supplied with an enable signal for controlling whether to activate the sense amplifier circuit SA. The enable signal can be, for example, a binary digital signal. When the potential of the wiring EL is a high potential, for example, the sense amplifier circuit SA can be in an activation state; the difference between the potential of the wiring BL and the potential of the wiring REF is amplified. On the other hand, when the potential of the wiring EL is a low potential, the sense amplifier circuit SA can be in a deactivation state; the amplification described above is not performed.

The wiring PRE can be supplied with a precharge signal for controlling whether to precharge the potentials of the wiring BL and the wiring REF. The precharge signal can be, for example, a binary digital signal. When the potential of the wiring PRE is a high potential, for example, the wiring BL can be precharged to a high potential. Furthermore, the potential of the wiring REF can be set to a potential between the potential of the wiring BL in the case where data “0” is read from the memory cells MC and the potential of the wiring BL in the case where data “1” is read from the memory cells MC.

Note that the same potential may be supplied to the wiring EL[1] to the wiring EL[n]. In this case, the wiring EL[1] to the wiring EL[n] can be electrically connected to each other. Furthermore, the same potential may be supplied to the wiring PRE[1] to the wiring PRE[n]. In this case, the wiring PRE[1] to the wiring PRE[n] can be electrically connected to each other.

Data output from the sense amplifier circuit SA is output from the wiring OUT. Data of the sense amplifier circuit SA[1] can be output from the wiring OUT[1]. Moreover, data of the sense amplifier circuit SA[n] can be output from the wiring OUT [n].

### Structure Example 1 of Memory Cell

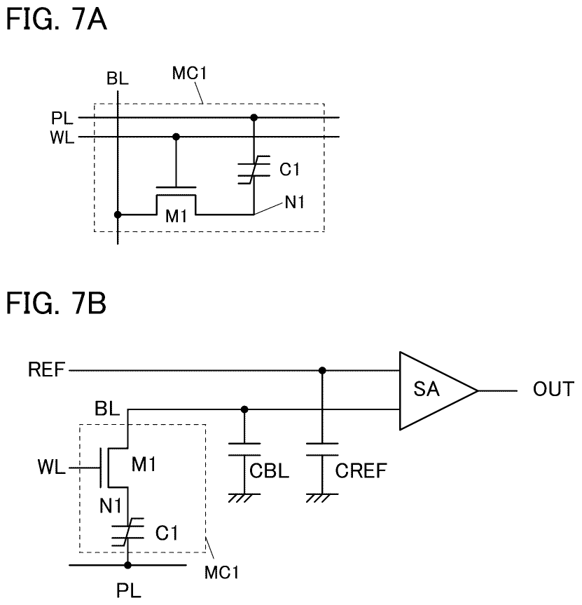

FIG. 7A is a circuit diagram of a memory cell that can be used for the memory cell MC1 in FIG. 6. The memory cell MC1 includes the transistor M1 and the ferroelectric capacitor C1. In the memory cell MC1, as shown in FIG. 7A, each element of the transistor M1 and the ferroelectric capacitor C1 is connected to the wiring BL, the wiring PL, and/or the wiring WL. In FIG. 7A, a wiring that electrically connects the transistor M1 and the ferroelectric capacitor C1 is shown as a node N1.

FIG. 7B shows an electrical connection between a sense amplifier circuit SA and each of the transistor M1, the ferroelectric capacitor C1, and the like included in the memory cell MC1. The wiring BL, the wiring REF, and the wiring OUT are connected to the sense amplifier circuit SA as shown in FIG. 7B. The sense amplifier circuit SA amplifies a difference between the potential of the wiring BL and the potential of the wiring REF. A load CBL and a load CREF, each of which is parasitic capacitance, are added to the wiring BL and the wiring REF, respectively. The loads CBL and CREF are provided as equivalent to each other. The description of the other structure shown in FIG. 7B is similar to that shown in FIG. 7A.

Data writing to the memory cell MC1 is performed by applying voltage to the ferroelectric capacitor C1. When a signal supplied to the wiring WL and the wiring BL is controlled to supply an H-level potential and an L-level potential to the node N1 and the wiring PL, respectively, a ferroelectric in the ferroelectric capacitor C1 is polarized to a state “1”. When an L-level potential and an H-level potential are supplied to the node N1 and the wiring PL, respectively, the ferroelectric in the ferroelectric capacitor C1 is polarized to a state “0”. As for the voltage applied to the node N1 and the wiring PL, L level can be 0 V, and H level can be 2.5 V, 3.3 V, or the like.

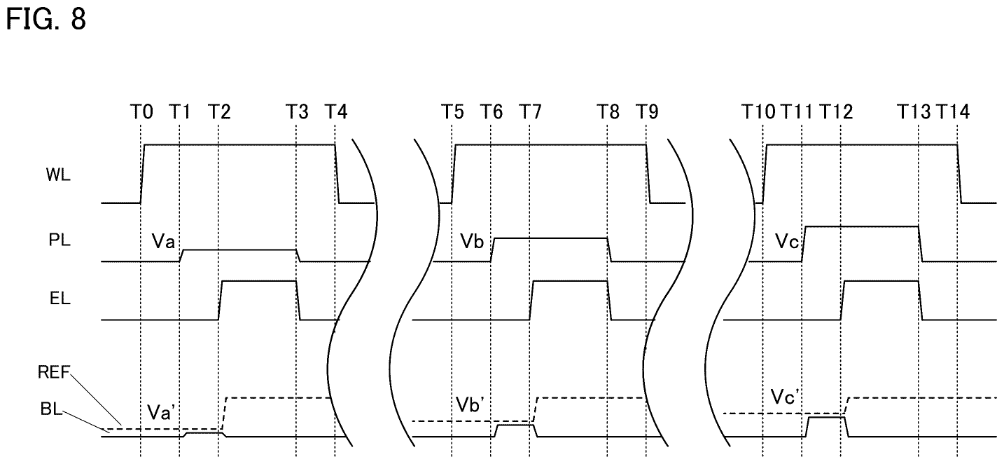

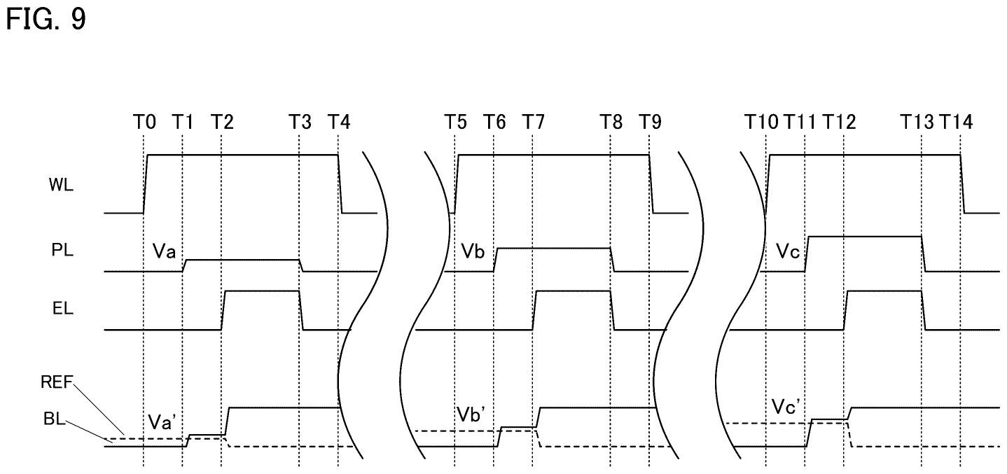

FIG. 8 and FIG. 9 each show a timing chart in the case of applying a reading operation of one embodiment of the present invention to the memory cell MC1 shown in FIG. 7A and FIG. 7B. FIG. 8 and FIG. 9 each show a timing chart of the data reading operation in the case where the ferroelectric in the ferroelectric capacitor C1 is polarized to the state “0” and in the case where the ferroelectric in the ferroelectric capacitor C1 is polarized to the state “1”, respectively.

In FIG. 8 and FIG. 9, the wiring WL is set to H level at Time T0 to turn on the transistor M1. A voltage Va is applied to the wiring PL at Time T1, so that the voltage of the wiring BL is boosted by capacitive coupling through the ferroelectric capacitor C1. At this time, a precharge voltage of the wiring REF is set to a voltage Va′ corresponding to the voltage Va. Here, the ferroelectric capacitor C1 is polarized to the state “0” in FIG. 8; therefore, the voltage of the wiring BL after being boosted is lower than that of the wiring REF. On the other hand, the ferroelectric capacitor C1 is polarized to the state “1” in FIG. 9; therefore, the voltage of the wiring BL after being boosted is higher than that of the wiring REF.

At Time T2, the wiring EL is set to H level. The enable signal of the sense amplifier circuit SA is supplied to the wiring EL and set to H level, so that the sense amplifier circuit SA is activated. When the wiring EL is set to H level, the sense amplifier circuit SA amplifies the potential difference between the wiring REF and the wiring BL. A signal corresponding to the potential difference is output to the wiring OUT.

Unlike the case where data is read from the ferroelectric capacitor C1 by destructive reading, the voltage for reading data does not exceed the polarization inversion voltage in the structure of one embodiment of the present invention. The polarization direction of the ferroelectric layer, therefore, is maintained before and after the reading operation. Thus, it can be unnecessary to apply a high voltage for writing back of data.

The wiring PL and the wiring EL are set to L level at Time T3. The sense amplifier circuit SA is inactivated. The wiring WL is set to L level at Time T4, whereby the transistor M1 is turned off and the reading operation is completed.

Subsequently, the second reading operation is performed after Time T5.

The wiring WL is set to H level to turn on the transistor M1 at Time T5. A voltage Vb (>the voltage Va) is applied to the wiring PL at Time T6, so that the voltage of the wiring BL is boosted by capacitive coupling through the ferroelectric capacitor C1. At this time, a precharge voltage of the wiring REF is set to a voltage Vb′ corresponding to the voltage Vb. Here, the ferroelectric capacitor C1 is polarized to the state “0” in FIG. 9; therefore, the voltage of the wiring BL after being boosted is lower than that of the wiring REF. On the other hand, the ferroelectric capacitor C1 is polarized to the state “1” in FIG. 9; therefore, the voltage of the wiring BL after being boosted is higher than that of the wiring REF.

The wiring EL is set to H level at Time T7, so that the sense amplifier circuit SA is activated. When the wiring EL is set to H level, the sense amplifier circuit SA amplifies the potential difference between the wiring REF and the wiring BL. A signal corresponding to the potential difference is output to the wiring OUT.

The wiring PL and the wiring EL are set to L level at Time T8, and the sense amplifier circuit SA is inactivated. The wiring WL is set to L level at Time T9, whereby the transistor M1 is turned off and the reading operation is completed.

Subsequently, the third reading operation is performed after Time T10.

The wiring WL is set to H level to turn on the transistor M1 at Time T10. A voltage Vc (>the voltage Vb) is applied to the wiring PL at Time T11, so that the voltage of the wiring BL is boosted by capacitive coupling through the ferroelectric capacitor C1. At this time, a precharge voltage of the wiring REF is set to a voltage Vc′ corresponding to the voltage Vc. Here, the ferroelectric capacitor C1 is polarized to the state “0” in FIG. 9; therefore, the voltage of the wiring BL after being boosted is lower than that of the wiring REF. On the other hand, the ferroelectric capacitor C1 is polarized to the state “1” in FIG. 9; therefore, the voltage of the wiring BL after being boosted is higher than that of the wiring REF.

The wiring EL is set to H level at Time T12, so that the sense amplifier circuit SA is activated. When the wiring EL is set to H level, the sense amplifier circuit SA amplifies the potential difference between the wiring REF and the wiring BL. A signal corresponding to the potential difference is output to the wiring OUT.

The wiring PL and the wiring EL are set to L level at Time T13, and the sense amplifier circuit SA is inactivated. The wiring WL is set to L level at Time T14, whereby the transistor M1 is turned off and the reading operation is completed.

In the above manner, by gradually increasing a drive voltage of the wiring PL and the precharge voltage of the wiring REF every time the reading operation is performed, the reading operation can be performed a plurality of times without performing data write-back operation to the ferroelectric capacitor C1.

Note that in the case where the voltage of the wiring PL is higher than or equal to a certain voltage (e.g., 3.3 V), a data refresh operation is preferably performed. In this case, the data refresh operation is performed by applying a high voltage to the ferroelectric capacitor C1.

It is effective to use a transistor including an oxide semiconductor in its channel formation region (an OS transistor) as the transistor M1 in each of FIG. 7A and FIG. 7B. Since the OS transistor has a high withstand voltage, miniaturization of each element included in the memory cell can be achieved by using the OS transistor in combination with a ferroelectric capacitor which has a high drive voltage. The OS transistor also has a feature of extremely low off-state current; therefore, the voltage of the node N1 can be retained for a long time. Note that the voltage of the node N1 might be decreased due to leakage current through the ferroelectric capacitor C1; however, leakage current can be reduced in the case where the electric field applied to the ferroelectric capacitor C1 is low.

When an OS transistor is used as the transistor M1 in FIG. 3, a data reading operation that utilizes electric charge held in the node N1 can be performed. Specifically, data can be read by distributing electric charge held in the node N1 to the wiring BL and amplifying the potential change by the sense amplifier. In the case where electric charge held in the node N1 is lost, electric charge may be supplied to the node N1 through the ferroelectric capacitor C1 by setting the voltage of the wiring PL to 3.0 V or more.

### Structure Example 2 of Memory Cell

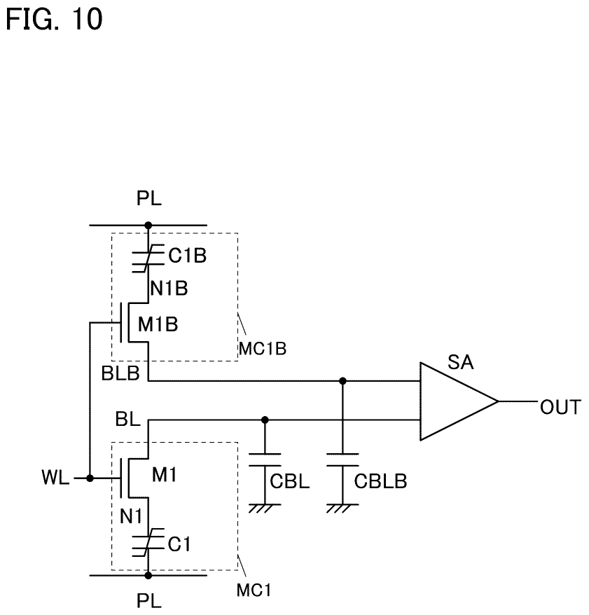

FIG. 10 is a structure example different from that in FIG. 7B. FIG. 10 shows an electrical connection between the sense amplifier circuit SA and each of the memory cell MC1 and a memory cell MC1B that stores inversion data of data written to the memory cell MC1. FIG. 10 shows a transistor M1B, a ferroelectric capacitor C1B, and a node N1B each included in the memory cell MC1B which makes a pair with the memory cell MC1. Hereinafter, a method for reading data from a memory cell that stores a pair of data sets is referred to as a twin cell type. FIG. 8 shows a wiring BLB to which the memory cell MC1B is connected. The sense amplifier circuit SA amplifies the potential difference between the wiring BL and the wiring BLB. The loads CBL and CBLB, each of which is parasitic capacitance, are added to the wiring BL and the wiring BLB. The loads CBL and CBLB are provided as equivalent to each other.

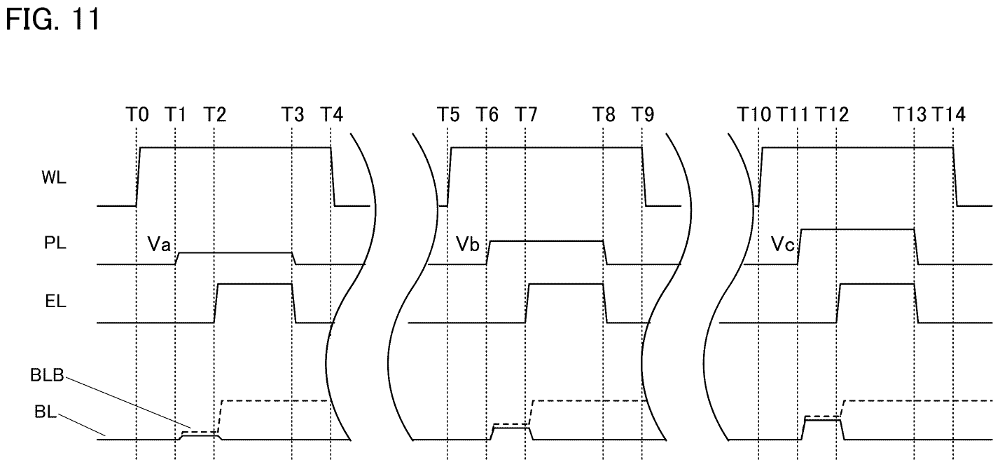

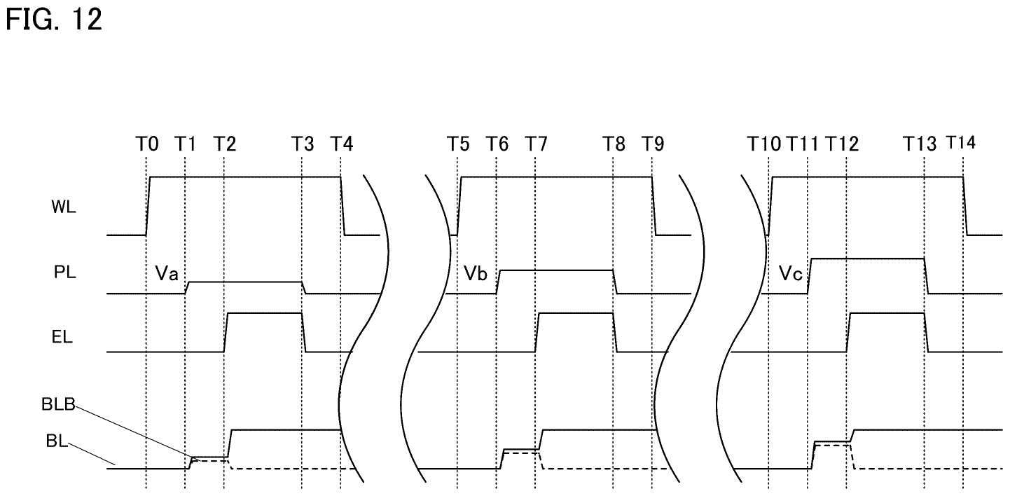

FIG. 11 and FIG. 12 each show a timing chart in the case of applying the reading operation of one embodiment of the present invention to the memory cells MC1 and MC1B shown in FIG. 10. FIG. 11 and FIG. 12 show timing charts of the data reading operation in the case where the ferroelectric in the ferroelectric capacitor C1 is polarized to the state “0” and in the case where the ferroelectric in the ferroelectric capacitor C1 is polarized to the state “1”, respectively. Note that the ferroelectric in the ferroelectric capacitor C1B is polarized to the state different from that in the ferroelectric capacitor C1.

The circuit structure in FIG. 10 is the twin cell type; therefore, the wiring REF shown in FIG. 7B is not included. Thus, the precharge voltage of the wiring REF does not need to be changed in accordance with the voltage of the wiring PL. In the data reading operation, the wiring BL and the wiring BLB may be set to, for example, an L-level potential for precharging. Since the circuit structure in FIG. 10 is the twin cell type, inversion data is written to each of the memory cell MC1 and the memory cell MC1B.

In FIG. 11 and FIG. 12, the wiring WL is set to H level at Time T0 to turn on the transistor M1 and the transistor M1B. The voltage Va is applied to the wiring PL at Time T1, so that the voltages of the wiring BL and the wiring BLB are boosted by capacitive coupling through the ferroelectric capacitor C1 and the ferroelectric capacitor C1B. Here, the ferroelectric capacitor C1 is polarized to the state “0” in FIG. 11 (the ferroelectric capacitor C1B is polarized to the state “1”); therefore, the voltage of the wiring BL after being boosted is lower than that of the wiring BLB. On the other hand, the ferroelectric capacitor C1 is polarized to the state “1” in FIG. 12 (the ferroelectric capacitor C1B is polarized to the state “0”); therefore, the voltage of the wiring BL after being boosted is higher than that of the wiring BLB.

At Time T2, the wiring EL is set to H level. The enable signal of the sense amplifier circuit SA is supplied to the wiring EL and set to H level, so that the sense amplifier circuit SA is activated. When the wiring EL is set to H level, the potential difference between the wiring BLB and the wiring BL is amplified. A signal corresponding to the potential difference is output to the wiring OUT.

Unlike the case where data is read from the ferroelectric capacitor C1 by destructive reading, the voltage for reading data does not exceed the polarization inversion voltage in the structure of one embodiment of the present invention. The polarization direction of the ferroelectric layer, therefore, is maintained before and after the reading operation. Thus, it can be unnecessary to apply a high voltage for writing back of data.

The wiring PL and the wiring EL are set to L level at Time T3, and the sense amplifier circuit SA is inactivated. The wiring WL is set to L level at Time T4, whereby the transistor M1 and the transistor M1B are turned off and the reading operation is completed.

Subsequently, the second reading operation is performed after Time T5.

The wiring WL is set to H level at Time T5 to turn on the transistor M1 and the transistor M1B. The voltage Vb (>the voltage Va) is applied to the wiring PL at Time T6, so that the voltages of the wiring BL and the wiring BLB are boosted by capacitive coupling through the ferroelectric capacitor C1 and the ferroelectric capacitor C1B. Here, the ferroelectric capacitor C1 is polarized to the state “0” in FIG. 11 (the ferroelectric capacitor C1B is polarized to the state “1”); therefore, the voltage of the wiring BL after being boosted is lower than that of the wiring BLB. On the other hand, the ferroelectric capacitor C1 is polarized to the state “1” in FIG. 12 (the ferroelectric capacitor C1B is polarized to the state “0”); therefore, the voltage of the wiring BL after being boosted is higher than that of the wiring BLB.

The wiring EL is set to H level at Time T7, so that the sense amplifier circuit SA is activated. When the wiring EL is set to H level, the sense amplifier circuit SA amplifies the potential difference between the wiring BLB and the wiring BL. A signal corresponding to the potential difference is output to the wiring OUT.

The wiring PL and the wiring EL are set to L level at Time T8, and the sense amplifier circuit SA is inactivated. The wiring WL is set to L level at Time T9, whereby the transistor M1 and the transistor M1B are turned off and the reading operation is completed.

Subsequently, the third reading operation is performed after Time T10.

The wiring WL is set to H level at Time T11 to turn on the transistor M1 and the transistor M1B. The voltage Vc (>the voltage Vb) is applied to the wiring PL at Time T12, so that the voltages of the wiring BL and the wiring BLB are boosted by capacitive coupling through the ferroelectric capacitor C1 and the ferroelectric capacitor C1B. Here, the ferroelectric capacitor C1 is polarized to the state “0” in FIG. 11 (the ferroelectric capacitor C1B is polarized to the state “1”); therefore, the voltage of the wiring BL after being boosted is lower than that of the wiring BLB. On the other hand, the ferroelectric capacitor C1 is polarized to the state “1” in FIG. 12 (the ferroelectric capacitor C1B is polarized to the state “0”); therefore, the voltage of the wiring BL after being boosted is higher than that of the wiring BLB.

The wiring EL is set to H level at Time T12, so that the sense amplifier circuit SA is activated. When the wiring EL is set to H level, the sense amplifier circuit SA amplifies the potential difference between the wiring BLB and the wiring BL. A signal corresponding to the potential difference is output to the wiring OUT.

The wiring PL and the wiring EL are set to L level at Time T13, and the sense amplifier circuit SA is inactivated. The wiring WL is set to L level at Time T14, whereby the transistor M1 and the transistor M1B are turned off and the reading operation is completed.

In the above manner, by gradually increasing a drive voltage of the wiring PL every time the reading operation is performed, the reading operation can be performed a plurality of times without performing data write-back operation to the ferroelectric capacitor C1.

Note that in the case where the voltage of the wiring PL is higher than or equal to a certain voltage (e.g., 3.3 V), the data refresh operation is preferably performed. In this case, the data refresh operation is performed by applying a high voltage to the ferroelectric capacitor C1 and the ferroelectric capacitor C1B.

It is effective to use a transistor including an oxide semiconductor in its channel formation region (an OS transistor) as each of the transistor M1 and the transistor M1B in FIG. 10, like the transistor M1 in each of FIG. 7A and FIG. 7B.

### Structure Example 3 of Memory Cell

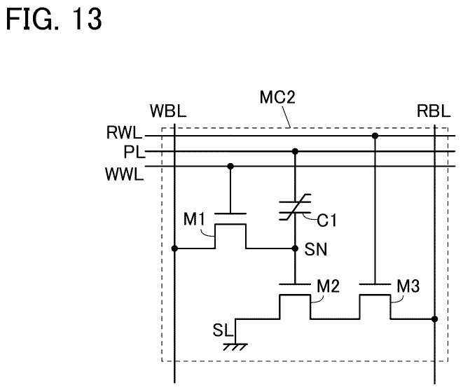

FIG. 13 is a circuit diagram of a memory cell different from the above-described memory cell MC1. A memory cell MC2 in FIG. 13 includes the transistor M1, a transistor M2, a transistor M3, and the ferroelectric capacitor C1. In the memory cell MC2, each element of the transistors M1 to M3 and the ferroelectric capacitor C1 is connected to a wiring WBL (also referred to as a write bit line), a wiring RBL (also referred to as a read bit line), the wiring PL, a wiring SL (also referred to as a source line), a wiring WWL (also referred to as a write word line), and/or a wiring RWL (also referred to as a reading word line) as shown in FIG. 13. In FIG. 13, a wiring electrically connecting the transistor M1, the transistor M2, and the ferroelectric capacitor C1 is denoted as a node SN.

In the memory cell MC2 in FIG. 13, the voltage of the wiring PL is changed to change the potential of the node SN owing to the capacitive coupling of the ferroelectric capacitor C1. At this time, there arises a difference in the potential of the node SN in accordance with a difference in polarization of the ferroelectric layer included in the ferroelectric capacitor C1, and the difference can be amplified in the transistor M2 to be read.

A wiring functioning as a bit line is divided into the wiring WBL and the wiring RBL, whereby a high voltage (e.g., 3.3 V) can be applied to the wiring WBL and data can be read from the wiring RBL at a low voltage (e.g., 1.2 V or less).

In the case where the reading operation is performed a plurality of times, it is effective to gradually increase the voltage of the wiring PL also in the structure in FIG. 13. When the voltage of the wiring PL is gradually increased, the voltage of the node SN is increased every time the reading operation is performed. Thus, a reading circuit connected to the wiring RBL has a function of adjusting the range of a read voltage in accordance with the number of times of reading.

Performing such driving can activate only the wiring RBL which is operable at a low voltage and inactivate the wiring WBL which requires a high voltage in normal reading operation, whereby power consumption can be reduced.

It is effective to use a transistor including an oxide semiconductor in its channel formation region (an OS transistor) as the transistors M1 and M3 in FIG. 13. Since the OS transistor has a feature of extremely low off-state current, the voltage of the node SN can be retained for a long time. Here, the voltage of the node SN might be decreased due to leakage current through the ferroelectric capacitor C1; however, leakage current can be reduced in the case where the electric field applied to the ferroelectric capacitor C1 is low.

When an OS transistor is used as the transistors M1 and M3 in FIG. 3, a data reading operation that utilizes electric charge held in the node SN can be performed. Specifically, data can be read by utilizing the fact that the amount of current flowing through the transistor M2 is determined in accordance with the potential corresponding to electric charge held in the node SN. In the case where the electric charge held in the node SN is lost, electric charge may be supplied to the node SN through the ferroelectric capacitor C1 by setting the voltage of the wiring PL to 3.0 V or more.

### Modification Example of Memory Cell

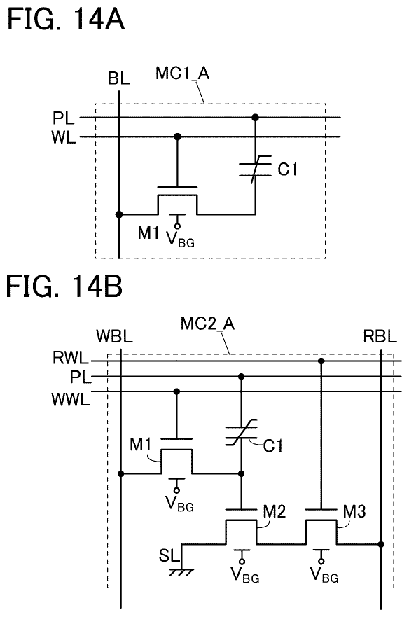

FIG. 14A is a circuit diagram showing a modification example of the above-described memory cell MC1. A memory cell MC1_A in FIG. 14A shows a structure in which the transistor M1 in the memory cell MC1 in FIG. 7A includes a back gate electrode to which a back gate voltage V_{BG} is applied. With the structure of FIG. 14A, the amount of current flowing through the transistors can be increased.

FIG. 14B is a circuit diagram showing a modification example of the above-described memory cell MC2. A memory cell MC2_A in FIG. 14B shows a structure in which each of the transistors M1 to M3 in the memory cell MC2 in FIG. 13 includes a back gate electrode to which the back gate voltage V_{BG} is applied. With the structure of FIG. 14B, the amount of current flowing through the transistors can be increased. Note that the back gate voltages applied to the back gates of the transistors may be the same or different from each other.

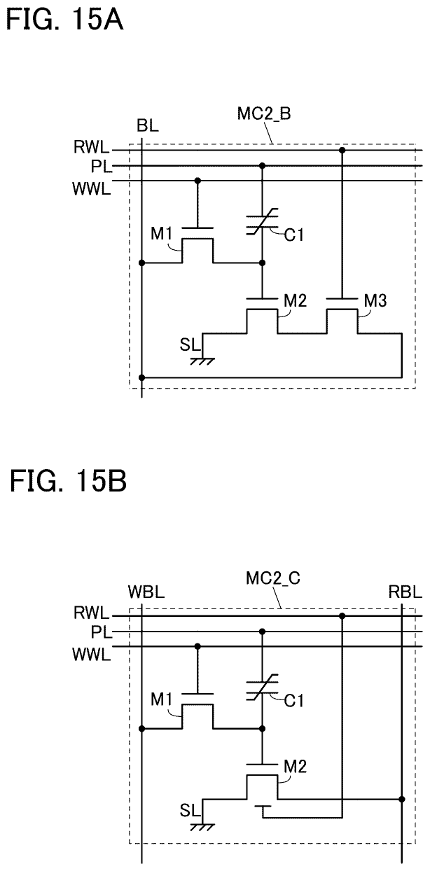

FIG. 15A is a circuit diagram showing a modification example of the above-described memory cell MC2. In a memory cell MC2_B shown in FIG. 15A, the wiring WBL and the wiring RBL in the memory cell MC2 in FIG. 13 are combined into the wiring BL. With the structure of FIG. 15A, the number of wirings connected to the memory cell can be reduced.

FIG. 15B is a circuit diagram showing a modification example of the above-described memory cell MC2. In a circuit diagram of a memory cell MC2_C shown in FIG. 15B, the transistor M3 in the memory cell MC2 in FIG. 13 is omitted, and the wiring RWL is connected to the back gate of the transistor M2. The selection signal supplied to the wiring RWL controls whether to flow current between the wiring RWL and the wiring SL by controlling the threshold voltage of the transistor M2. With the structure of FIG. 15B, the number of transistors included in the memory cell can be reduced.

As described above, in one embodiment of the present invention, the polarization direction of the remnant polarization of the ferroelectric layer FE is not completely inverted but partially inverted in the operation for applying electric fields to read data. The balance of the polarization direction of the remnant polarization of the ferroelectric layer FE is collapsed as the reading operation is repeated; thus, in the reading operation, voltage applied to the counter electrode of the ferroelectric capacitor is gradually increased so as not to cause polarization destruction in the ferroelectric capacitor. This structure enables data to be read even when the remnant polarization of the ferroelectric layer FE becomes small by repeated reading operation.

This embodiment can be combined with any of the other embodiments described in this specification as appropriate.

### Embodiment 3

Described in this embodiment is a metal oxide (hereinafter also referred to as an oxide semiconductor) that can be used in an OS transistor described in the above embodiment.

The metal oxide preferably contains at least indium or zinc. In particular, indium and zinc are preferably contained. In addition to them, aluminum, gallium, yttrium, tin, or the like is preferably contained. Furthermore, one or more kinds selected from boron, silicon, titanium, iron, nickel, germanium, zirconium, molybdenum, lanthanum, cerium, neodymium, hafnium, tantalum, tungsten, magnesium, cobalt, and the like may be contained.

### Classification of Crystal Structures

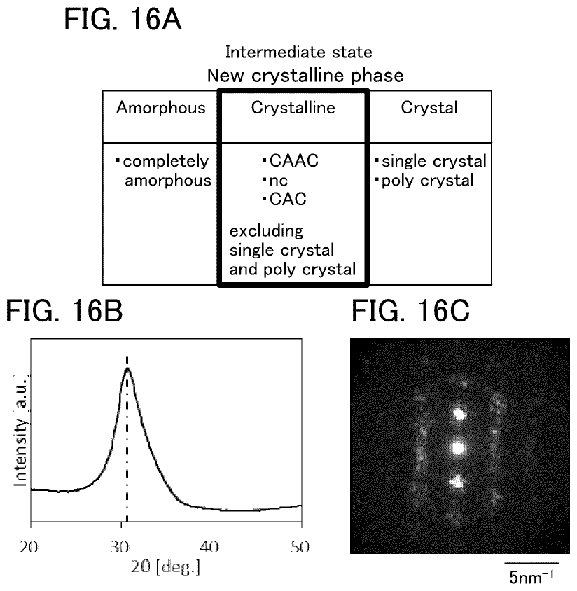

First, the classification of crystal structures of an oxide semiconductor is described with reference to FIG. 16A. FIG. 16A is a diagram showing classification of crystal structures of an oxide semiconductor, typically IGZO (a metal oxide containing In, Ga, and Zn).

As shown in FIG. 16A, an oxide semiconductor is roughly classified into “Amorphous”, “Crystalline”, and “Crystal”. The term “Amorphous” includes completely amorphous. The term “Crystalline” includes CAAC (c-axis-aligned crystalline), nc (nanocrystalline), and CAC (Cloud-Aligned Composite). Note that the term “Crystalline” excludes single crystal, poly crystal, and completely amorphous. The term “Crystal” includes single crystal and poly crystal.

Note that the structures in the thick frame in FIG. 16A are in an intermediate state between “Amorphous” and “Crystal”, and belong to a new crystalline phase. That is, these structures are completely different from “Amorphous”, which is energetically unstable, and “Crystal”.

A crystal structure of a film or a substrate can be analyzed with an X-ray diffraction (XRD) spectrum. FIG. 16B shows an XRD spectrum, which is obtained by GIXD (Grazing-Incidence XRD) measurement, of a CAAC-IGZO film classified into “Crystalline” (the vertical axis represents intensity in arbitrary unit (a.u.)). Note that a GIXD method is also referred to as a thin film method or a Seemann-Bohlin method. The XRD spectrum that is shown in FIG. 16B and obtained by GIXD measurement is hereinafter simply referred to as an XRD spectrum. The CAAC-IGZO film shown in FIG. 16B has a composition in the vicinity of In:Ga:Zn=4:2:3 [atomic ratio]. The CAAC-IGZO film shown in FIG. 16B has a thickness of 500 nm.

As shown in FIG. 16B, a clear peak indicating crystallinity is detected in the XRD spectrum of the CAAC-IGZO film. Specifically, a peak indicating c-axis alignment is detected at or around 2θ=31° in the XRD spectrum of the CAAC-IGZO film. As shown in FIG. 16B, the peak at or around 2θ=31° is asymmetric with respect to the axis of the angle at which the peak intensity is detected.

A crystal structure of a film or a substrate can also be evaluated with a diffraction pattern obtained by a nanobeam electron diffraction (NBED) method (such a pattern is also referred to as a nanobeam electron diffraction pattern). FIG. 16C shows a diffraction pattern of a CAAC-IGZO film. FIG. 16C shows a diffraction pattern obtained with the NBED method in which an electron beam is incident in the direction parallel to the substrate. The CAAC-IGZO film in FIG. 16C has a composition in the vicinity of In:Ga:Zn=4:2:3 [atomic ratio]. In the nanobeam electron diffraction method, electron diffraction is performed with a probe diameter of 1 nm.

As shown in FIG. 16C, a plurality of spots indicating c-axis alignment are observed in the diffraction pattern of the CAAC-IGZO film.

### Structure of Oxide Semiconductor

Oxide semiconductors might be classified in a manner different from that in FIG. 16A when classified in terms of the crystal structure. Oxide semiconductors are classified into a single crystal oxide semiconductor and a non-single-crystal oxide semiconductor, for example. Examples of the non-single-crystal oxide semiconductor include the above-described CAAC-OS and nc-OS. Other examples of the non-single-crystal oxide semiconductor include a polycrystalline oxide semiconductor, an amorphous-like oxide semiconductor (a-like OS), and an amorphous oxide semiconductor.

Here, the above-described CAAC-OS, nc-OS, and a-like OS are described in detail.

### [CAAC-OS]

The CAAC-OS is an oxide semiconductor that has a plurality of crystal regions each of which has c-axis alignment in a particular direction. Note that the particular direction refers to the thickness direction of a CAAC-OS film, the normal direction of the surface where the CAAC-OS film is formed, or the normal direction of the surface of the CAAC-OS film. The crystal region refers to a region with a periodic atomic arrangement. When an atomic arrangement is regarded as a lattice arrangement, the crystal region also refers to a region with a uniform lattice arrangement. The CAAC-OS has a region where a plurality of crystal regions are connected in the a-b plane direction, and the region has distortion in some cases. Note that the distortion refers to a portion where the direction of a lattice arrangement changes between a region with a uniform lattice arrangement and another region with a uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more fine crystals (crystals each of which has a maximum diameter of less than 10 nm). In the case where the crystal region is formed of one fine crystal, the maximum diameter of the crystal region is less than 10 nm. In the case where the crystal region is formed of a large number of fine crystals, the size of the crystal region may be approximately several tens of nanometers.

In the case of an In-M-Zn oxide (the element M is one or more kinds selected from aluminum, gallium, yttrium, tin, titanium, and the like), the CAAC-OS tends to have a layered crystal structure (also referred to as a layered structure) in which layers containing indium (In) and oxygen (hereinafter In layers) and layers containing the element M, zinc (Zn), and oxygen (hereinafter (M,Zn) layers) are stacked. Indium and the element M can be replaced with each other. Therefore, indium may be contained in the (M,Zn) layer. In addition, the element M may be contained in the In layer. Note that Zn may be contained in the In layer. Such a layered structure is observed as a lattice image in a high-resolution TEM image, for example.

When the CAAC-OS film is subjected to structural analysis by out-of-plane XRD measurement with an XRD apparatus using 191219 scanning, for example, a peak indicating c-axis alignment is detected at 2θ of 31° or around 31°. Note that the position of the peak indicating c-axis alignment (the value of 2θ may change depending on the kind, composition, or the like of the metal element contained in the CAAC-OS.

For example, a plurality of bright spots are observed in the electron diffraction pattern of the CAAC-OS film. Note that one spot and another spot are observed point-symmetrically with a spot of the incident electron beam passing through a sample (also referred to as a direct spot) as the symmetric center.

When the crystal region is observed from the particular direction, a lattice arrangement in the crystal region is basically a hexagonal lattice arrangement; however, a unit lattice is not always a regular hexagon and is a non-regular hexagon in some cases. A pentagonal lattice arrangement, a heptagonal lattice arrangement, or the like is included in the distortion in some cases. Note that a clear grain boundary cannot be observed even in the vicinity of the distortion in the CAAC-OS. That is, formation of a grain boundary is inhibited by the distortion of lattice arrangement. This is probably because the CAAC-OS can tolerate distortion owing to a low density of arrangement of oxygen atoms in the a-b plane direction, an interatomic bond distance changed by substitution of a metal atom, and the like.

A crystal structure in which a clear grain boundary is observed is what is called polycrystal. It is highly probable that the grain boundary becomes a recombination center and captures carriers and thus decreases the on-state current or field-effect mobility of a transistor, for example. Thus, the CAAC-OS in which no clear grain boundary is observed is one of crystalline oxides having a crystal structure suitable for a semiconductor layer of a transistor. Note that Zn is preferably contained to form the CAAC-OS. For example, an In—Zn oxide and an In—Ga—Zn oxide are suitable because they can inhibit generation of a grain boundary as compared with an In oxide.

The CAAC-OS is an oxide semiconductor with high crystallinity in which no clear grain boundary is observed. Thus, in the CAAC-OS, a reduction in electron mobility due to the grain boundary is unlikely to occur. Moreover, since the crystallinity of an oxide semiconductor might be decreased by entry of impurities, formation of defects, and the like, the CAAC-OS can be regarded as an oxide semiconductor that has small amounts of impurities, defects (e.g., oxygen vacancies), and the like. Thus, an oxide semiconductor including the CAAC-OS is physically stable. Therefore, the oxide semiconductor including the CAAC-OS is resistant to heat and has high reliability. In addition, the CAAC-OS is stable with respect to high temperature in the manufacturing process (what is called thermal budget). Accordingly, the use of the CAAC-OS for an OS transistor can extend the degree of freedom of the manufacturing process.

[nc-OS]

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a fine crystal. Note that the size of the fine crystal is, for example, greater than or equal to 1 nm and less than or equal to 10 nm, particularly greater than or equal to 1 nm and less than or equal to 3 nm; thus, the fine crystal is also referred to as a nanocrystal. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor with some analysis methods. For example, when an nc-OS film is subjected to structural analysis using out-of-plane XRD measurement with an XRD apparatus using θ/2θ scanning, a peak indicating crystallinity is not detected. Furthermore, a diffraction pattern like a halo pattern is observed when the nc-OS film is subjected to electron diffraction (also referred to as selected-area electron diffraction) using an electron beam with a probe diameter larger than the diameter of a nanocrystal (e.g., larger than or equal to 50 nm). Meanwhile, in some cases, a plurality of spots in a ring-like region with a direct spot as the center are observed in the obtained electron diffraction pattern when the nc-OS film is subjected to electron diffraction (also referred to as nanobeam electron diffraction) using an electron beam with a probe diameter nearly equal to or smaller than the diameter of a nanocrystal (e.g., 1 nm or larger and 30 nm or smaller).

[a-like OS]

The a-like OS is an oxide semiconductor having a structure between those of the nc-OS and the amorphous oxide semiconductor. The a-like OS includes a void or a low-density region. That is, the a-like OS has lower crystallinity than the nc-OS and the CAAC-OS. Moreover, the a-like OS has a higher hydrogen concentration in the film than the nc-OS and the CAAC-OS.

### <<Composition of Oxide Semiconductor>>

Next, the above-described CAC-OS is described in detail. Note that the CAC-OS relates to the material composition.

### [CAC-OS]

The CAC-OS refers to one composition of a material in which elements constituting a metal oxide are unevenly distributed with a size greater than or equal to 0.5 nm and less than or equal to 10 nm, preferably greater than or equal to 1 nm and less than or equal to 3 nm, or a similar size, for example. Note that a state in which one or more metal elements are unevenly distributed and regions including the metal element(s) are mixed with a size greater than or equal to 0.5 nm and less than or equal to 10 nm, preferably greater than or equal to 1 nm and less than or equal to 3 nm, or a similar size in a metal oxide is hereinafter referred to as a mosaic pattern or a patch-like pattern.

In addition, the CAC-OS has a composition in which materials are separated into a first region and a second region to form a mosaic pattern, and the first regions are distributed in the film (this composition is hereinafter also referred to as a cloud-like composition). That is, the CAC-OS is a composite metal oxide having a composition in which the first regions and the second regions are mixed.

Here, the atomic ratios of In, Ga, and Zn to the metal elements contained in the CAC-OS in an In—Ga—Zn oxide are denoted with [In], [Ga], and [Zn], respectively. For example, the first region in the CAC-OS in the In—Ga—Zn oxide has [In] higher than that in the composition of the CAC-OS film. Moreover, the second region has [Ga] higher than that in the composition of the CAC-OS film. As another example, the first region has higher [In] and lower [Ga] than the second region. Moreover, the second region has higher [Ga] and lower [In] than the first region.

Specifically, the first region includes indium oxide, indium zinc oxide, or the like as its main component. The second region includes gallium oxide, gallium zinc oxide, or the like as its main component. That is, the first region can be referred to as a region containing In as its main component. The second region can be referred to as a region containing Ga as its main component.

Note that a clear boundary between the first region and the second region cannot be observed in some cases.

For example, energy dispersive X-ray spectroscopy (EDX) is used to obtain EDX mapping, and according to the EDX mapping, the CAC-OS in the In—Ga—Zn oxide has a structure in which the region containing In as its main component (the first region) and the region containing Ga as its main component (the second region) are unevenly distributed and mixed.

In the case where the CAC-OS is used for a transistor, a switching function (On/Off switching function) can be given to the CAC-OS owing to the complementary action of the conductivity derived from the first region and the insulating property derived from the second region. That is, the CAC-OS has a conducting function in part of the material and has an insulating function in another part of the material; as a whole, the CAC-OS has a function of a semiconductor. Separation of the conducting function and the insulating function can maximize each function. Accordingly, when the CAC-OS is used for a transistor, a high on-state current (Iₒₙ), high field-effect mobility (μ), and an excellent switching operation can be achieved.

An oxide semiconductor has various structures with different properties. Two or more kinds among the amorphous oxide semiconductor, the polycrystalline oxide semiconductor, the a-like OS, the CAC-OS, the nc-OS, and the CAAC-OS may be included in an oxide semiconductor of one embodiment of the present invention.

### Transistor Including Oxide Semiconductor

Next, the case where the above oxide semiconductor is used for a transistor is described.

When the above oxide semiconductor is used for a transistor, a transistor with high field-effect mobility can be achieved. In addition, a transistor having high reliability can be achieved.

An oxide semiconductor with a low carrier concentration is preferably used for a transistor. For example, the carrier concentration of an oxide semiconductor is lower than or equal to 1×10¹⁷ cm⁻³, preferably lower than or equal to 1×10¹⁵ cm⁻³, further preferably lower than or equal to 1×10¹³ cm⁻³, still further preferably lower than or equal to 1×10¹¹ cm⁻³, yet further preferably lower than 1×10¹⁰ cm⁻³, and higher than or equal to 1×10⁻⁹ cm⁻³. In order to reduce the carrier concentration of an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and thus has a low density of trap states in some cases.

Electric charge trapped by the trap states in the oxide semiconductor takes a long time to disappear and might behave like fixed electric charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film be also reduced. Examples of impurities include hydrogen, nitrogen, an alkali metal, an alkaline earth metal, iron, nickel, and silicon.

### Impurities>

Here, the influence of each impurity in the oxide semiconductor is described.

When silicon or carbon, which is one of Group 14 elements, is contained in the oxide semiconductor, defect states are formed in the oxide semiconductor. Thus, the concentration of silicon or carbon in the oxide semiconductor and the concentration of silicon or carbon in the vicinity of an interface with the oxide semiconductor (the concentration obtained by secondary ion mass spectrometry (SIMS)) are each set lower than or equal to 2×10¹⁸ atoms/cm³, preferably lower than or equal to 2×10¹⁷ atoms/cm³.

When the oxide semiconductor contains an alkali metal or an alkaline earth metal, defect states are formed and carriers are generated in some cases. Thus, a transistor using an oxide semiconductor that contains an alkali metal or an alkaline earth metal is likely to have normally-on characteristics. Thus, the concentration of an alkali metal or an alkaline earth metal in the oxide semiconductor, which is obtained using SIMS, is set lower than or equal to 1×10¹⁸ atoms/cm³, preferably lower than or equal to 2×10¹⁶ atoms/cm³.

When the oxide semiconductor contains nitrogen, the oxide semiconductor easily becomes n-type because of generation of electrons serving as carriers and an increase in carrier concentration. As a result, a transistor using an oxide semiconductor containing nitrogen as a semiconductor is likely to have normally-on characteristics. When nitrogen is contained in the oxide semiconductor, a trap state is sometimes formed. This might make the electrical characteristics of the transistor unstable. Therefore, the concentration of nitrogen in the oxide semiconductor, which is obtained using SIMS, is set lower than 5×10¹⁹ atoms/cm³, preferably lower than or equal to 5×10¹⁸ atoms/cm³, further preferably lower than or equal to 1×10¹⁸ atoms/cm³, still further preferably lower than or equal to 5×10¹⁷ atoms/cm³. Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor using an oxide semiconductor containing hydrogen is likely to have normally-on characteristics. Accordingly, hydrogen in the oxide semiconductor is preferably reduced as much as possible. Specifically, the hydrogen concentration in the oxide semiconductor, which is obtained using SIMS, is set lower than 1×10²⁰ atoms/cm³, preferably lower than 1×10¹⁹ atoms/cm³, further preferably lower than 5×10¹⁸ atoms/cm³, and still further preferably lower than 1×10¹⁸ atoms/cm³.

When an oxide semiconductor with sufficiently reduced impurities is used for the channel formation region of the transistor, stable electrical characteristics can be given.

Note that this embodiment can be combined with any of the other embodiments described in this specification as appropriate.

### Embodiment 4

Described in this embodiment are examples of a semiconductor wafer where the semiconductor device or the like described in the above embodiment is formed and electronic components incorporating the semiconductor device.

### Semiconductor Wafer

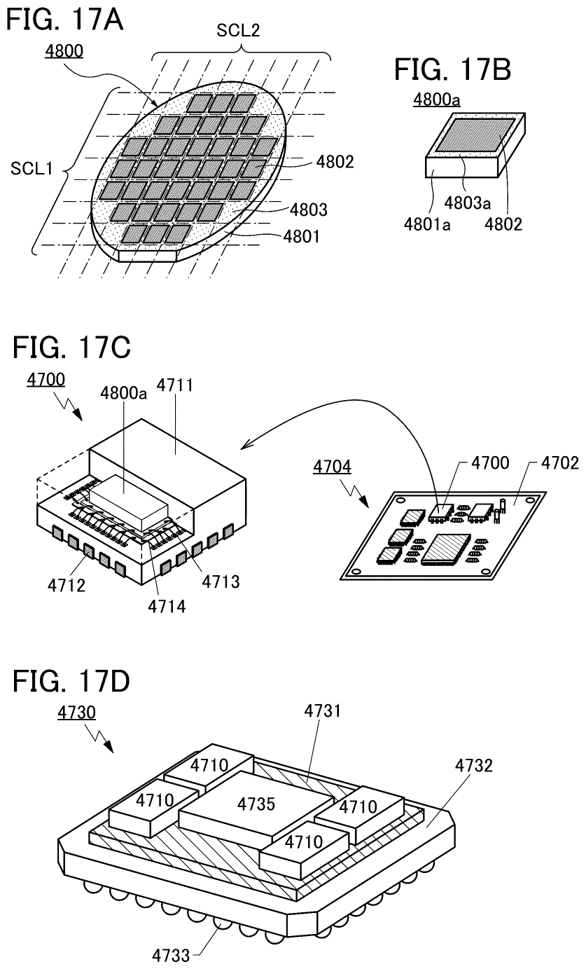

First, an example of a semiconductor wafer where a semiconductor device or the like is formed is described using FIG. 17A.

A semiconductor wafer 4800 illustrated in FIG. 17A includes a wafer 4801 and a plurality of circuit portions 4802 provided on a top surface of the wafer 4801. Note that a portion without the circuit portion 4802 on the top surface of the wafer 4801 is a spacing 4803 that is a region for dicing.

The semiconductor wafer 4800 can be manufactured by forming the plurality of circuit portions 4802 on the surface of the wafer 4801 by a pre-process. After that, a surface of the wafer 4801 opposite to the surface provided with the plurality of circuit portions 4802 may be ground to thin the wafer 4801. Through this step, for example, warpage of the wafer 4801 is reduced and the size of the component can be reduced.

A dicing step is performed as a next step. Dicing is performed along scribe lines SCL1 and scribe lines SCL2 (referred to as dicing lines or cutting lines in some cases) indicated by dashed-dotted lines. Note that to perform the dicing step easily, it is preferable that the spacing 4803 be provided so that the plurality of scribe lines SCL1 are parallel to each other, the plurality of scribe lines SCL2 are parallel to each other, and the scribe lines SCL1 are perpendicular to the scribe lines SCL2.

With the dicing step, a chip 4800a as illustrated in FIG. 17B can be cut out from the semiconductor wafer 4800. The chip 4800a includes a wafer 4801a, the circuit portion 4802, and a spacing 4803a. Note that it is preferable to make the spacing 4803a small as much as possible. In this case, the width of the spacing 4803 between adjacent circuit portions 4802 is substantially the same as a cutting allowance of the scribe line SCL1 or a cutting allowance of the scribe line SCL2.

Note that the shape of the element substrate of one embodiment of the present invention is not limited to the shape of the semiconductor wafer 4800 illustrated in FIG. 17A. The element substrate may be a rectangular semiconductor wafer, for example. The shape of the element substrate can be changed as appropriate, depending on a manufacturing process of an element and an apparatus for manufacturing the element.

### Electronic Component

FIG. 17C illustrates a perspective view of an electronic component 4700 and a substrate (a mounting board 4704) on which the electronic component 4700 is mounted. The electronic component 4700 illustrated in FIG. 17C includes a chip 4800a in a mold 4711. As the chip 4800a, the memory device of one embodiment of the present invention can be used, for example.

To illustrate the inside of the electronic component 4700, some portions are omitted in FIG. 17C. The electronic component 4700 includes a land 4712 outside the mold 4711. The land 4712 is electrically connected to an electrode pad 4713, and the electrode pad 4713 is electrically connected to the chip 4800a through a wire 4714. The electronic component 4700 is mounted on a printed circuit board 4702, for example. A plurality of such electronic components are combined and electrically connected to each other on the printed circuit board 4702, so that the mounting board 4704 is completed.

FIG. 17D illustrates a perspective view of an electronic component 4730. The electronic component 4730 is an example of a SiP (System in package) or an MCM (Multi Chip Module). In the electronic component 4730, an interposer 4731 is provided on a package substrate 4732 (a printed circuit board), and a semiconductor device 4735 and a plurality of semiconductor devices 4710 are provided on the interposer 4731.

Examples of the semiconductor device 4710 include the chip 4800a, the semiconductor device described in the above embodiment, and a high bandwidth memory (HBM). In addition, an integrated circuit (a semiconductor device) such as a CPU, a GPU, an FPGA, or a memory device can be used as the semiconductor device 4735.

As the package substrate 4732, a ceramic substrate, a plastic substrate, a glass epoxy substrate, or the like can be used. As the interposer 4731, a silicon interposer, a resin interposer, or the like can be used.

The interposer 4731 includes a plurality of wirings and has a function of electrically connecting a plurality of integrated circuits with different terminal pitches. The plurality of wirings are provided in a single layer or multiple layers. In addition, the interposer 4731 has a function of electrically connecting an integrated circuit provided on the interposer 4731 to an electrode provided on the package substrate 4732. Accordingly, the interposer is referred to as a “redistribution substrate” or an “intermediate substrate” in some cases. Furthermore, a through electrode is provided in the interposer 4731 and the through electrode is used to electrically connect an integrated circuit and the package substrate 4732 in some cases. Moreover, in the case of using a silicon interposer, a TSV (Through Silicon Via) can also be used as the through electrode.

A silicon interposer is preferably used as the interposer 4731. The silicon interposer can be manufactured at lower cost than an integrated circuit because it is not necessary to provide an active element. Moreover, since wirings of the silicon interposer can be formed through a semiconductor process, the formation of minute wirings, which is difficult for a resin interposer, is easily achieved.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP, an MCM, or the like using a silicon interposer, a decrease in reliability due to a difference in the coefficient of expansion between an integrated circuit and the interposer is less likely to occur. Furthermore, a surface of a silicon interposer has high planarity; thus, poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

A heat sink (a radiator plate) may be provided to overlap with the electronic component 4730. In the case of providing a heat sink, the heights of integrated circuits provided on the interposer 4731 are preferably equal to each other. For example, in the electronic component 4730 described in this embodiment, the heights of the semiconductor devices 4710 and the semiconductor device 4735 are preferably equal to each other.

To mount the electronic component 4730 on another substrate, an electrode 4733 may be provided on a bottom portion of the package substrate 4732. FIG. 17D illustrates an example in which the electrode 4733 is formed of a solder ball. Solder balls are provided in a matrix on the bottom portion of the package substrate 4732, so that BGA (Ball Grid Array) mounting can be achieved. Alternatively, the electrode 4733 may be formed of a conductive pin. When conductive pins are provided in a matrix on the bottom portion of the package substrate 4732, PGA (Pin Grid Array) mounting can be achieved.

The electronic component 4730 can be mounted on another substrate by various mounting methods not limited to BGA and PGA. For example, a mounting method such as SPGA (Staggered Pin Grid Array), LGA (Land Grid Array), QFP (Quad Flat Package), QFJ (Quad Flat J-leaded package), or QFN (Quad Flat Non-leaded package) can be employed.

The structure described in this embodiment can be combined with any of the structures described in the other embodiments as appropriate.

### Embodiment 5

In this embodiment, application examples of the semiconductor device of one embodiment of the present invention will be described.

The semiconductor device of one embodiment of the present invention can be applied to, for example, memory devices of a variety of electronic devices (e.g., information terminals, computers, smartphones, e-book readers, digital still cameras, video cameras, video recording/reproducing devices, navigation systems, game machines, and the like). In addition, the semiconductor device can also be used for image sensors, IoT (Internet of Things), healthcare-related devices, and the like. Note that here, the computers refer not only to tablet computers, laptop computers, and desktop computers, but also to large computers such as server systems.

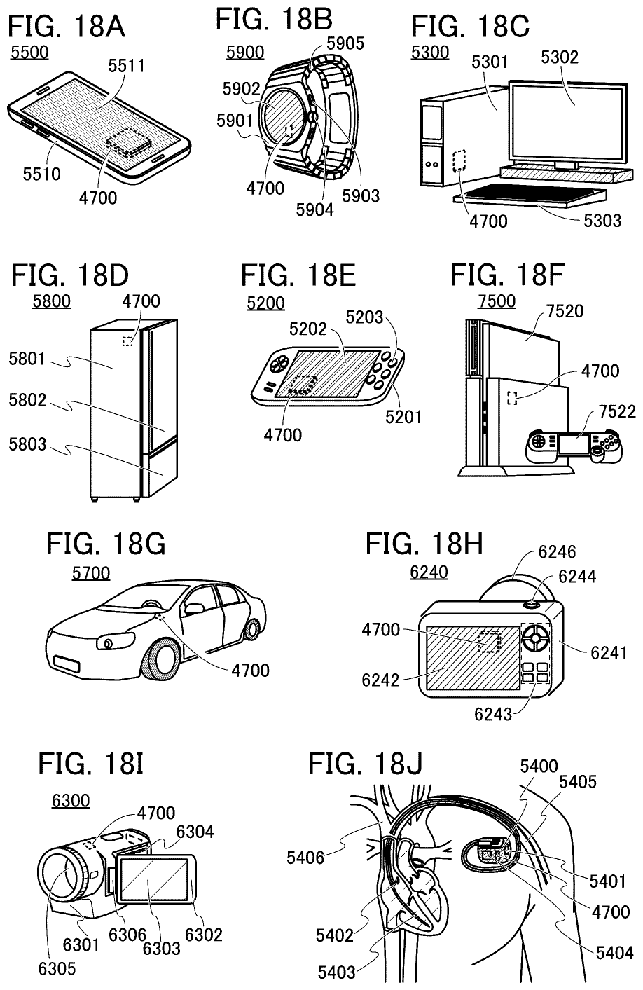

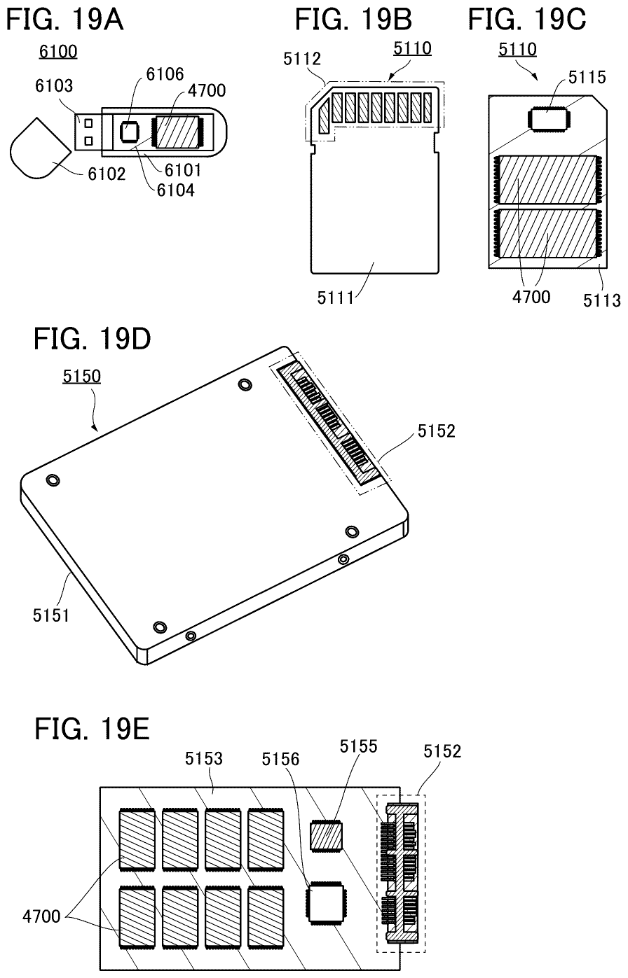

An example of an electronic device including a semiconductor device of one embodiment of the present invention is described. Note that FIG. 18A to FIG. 18J and FIG. 19A to FIG. 19E each illustrate a state where the electronic component 4700 or the electronic component 4730, each of which includes the semiconductor device, is included in an electronic device.

### [Cellular Phone]

An information terminal 5500 illustrated in FIG. 18A is a cellular phone (smartphone), which is a type of information terminal. The information terminal 5500 includes a housing 5510 and a display portion 5511, and as input interfaces, a touch panel is provided in the display portion 5511 and a button is provided in the housing 5510.

By employing the semiconductor device of one embodiment of the present invention for the information terminal 5500, the information terminal 5500 can retain a temporary file generated at the time of executing an application (e.g., a web browser's cache).

### [Wearable Terminal]

In addition, FIG. 18B illustrates an information terminal 5900 that is an example of a wearable terminal. The information terminal 5900 includes a housing 5901, a display portion 5902, an operation switch 5903, an operation switch 5904, a band 5905, and the like

Like the information terminal 5500 described above, the wearable terminal can retain a temporary file generated at the time of executing an application by employing the semiconductor device of one embodiment of the present invention for the wearable terminal.

### [Information Terminal]

In addition, FIG. 18C illustrates a desktop information terminal 5300. The desktop information terminal 5300 includes a main body 5301 of the information terminal, a display portion 5302, and a keyboard 5303.

Like the information terminal 5500 described above, the desktop information terminal 5300 can retain a temporary file generated at the time of executing an application by employing the semiconductor device of one embodiment of the present invention for the desktop information terminal 5300.

Although the smartphone, the wearable terminal, and the desktop information terminal are respectively illustrated in FIG. 18A to FIG. 18C as examples of the electronic device, one embodiment of the present invention can be employed for an information terminal other than a smartphone, a wearable terminal, and a desktop information terminal. Examples of information terminals other than a smartphone, a wearable terminal, and a desktop information terminal include a PDA (Personal Digital Assistant), a laptop information terminal, and a workstation.

### [Household Appliance]

FIG. 18D illustrates an electric refrigerator-freezer 5800 as an example of a household appliance. The electric refrigerator-freezer 5800 includes a housing 5801, a refrigerator door 5802, a freezer door 5803, and the like. For example, the electric refrigerator-freezer 5800 is an electric refrigerator-freezer that is compatible with IoT (Internet of Things).

The semiconductor device of one embodiment of the present invention can be employed for the electric refrigerator-freezer 5800. The electric refrigerator-freezer 5800 can transmit and receive information on food stored in the electric refrigerator-freezer 5800 or food expiration dates, for example, to and from an information terminal or the like via the Internet or the like. In the electric refrigerator-freezer 5800, the semiconductor device can retain a temporary file generated at the time of transmitting the information.

Although the electric refrigerator-freezer is described in this example as a household appliance, examples of other household appliances include a vacuum cleaner, a microwave oven, an electric oven, a rice cooker, a water heater, an IH cooker, a water server, a heating-cooling combination appliance such as an air conditioner, a washing machine, a drying machine, an audiovisual appliance, and the like.

### [Game Machine]

FIG. 18E illustrates a portable game machine 5200 as an example of a game machine. The portable game machine 5200 includes a housing 5201, a display portion 5202, a button 5203, and the like.

FIG. 18F illustrates a stationary game machine 7500 as another example of a game machine. The stationary game machine 7500 includes a main body 7520 and a controller 7522. Note that the controller 7522 can be connected to the main body 7520 with or without a wire. Furthermore, although not illustrated in FIG. 18F, the controller 7522 can include a display portion that displays a game image, and an input interface besides a button, such as a touch panel, a stick, a rotating knob, and a sliding knob, for example. The shape of the controller 7522 is not limited to that illustrated in FIG. 18F, and the shape of the controller 7522 may be changed in various ways in accordance with the genres of games. For example, for a shooting game such as an FPS (First Person Shooter) game, a gun-shaped controller having a trigger button can be used. As another example, for a music game or the like, a controller having a shape of a musical instrument, audio equipment, or the like can be used. Furthermore, the stationary game machine may include a camera, a depth sensor, a microphone, and the like so that the game player can play a game using a gesture and/or a voice instead of a controller.

In addition, videos displayed on the game machine can be output with a display device such as a television device, a personal computer display, a game display, or a head-mounted display.

The semiconductor device described in the above embodiment is employed for the portable game machine 5200 or the stationary game machine 7500, so that the portable game machine 5200 with low power consumption or the stationary game machine 7500 with low power consumption can be achieved. Moreover, heat generation from a circuit can be reduced owing to low power consumption; thus, the influence of heat generation on the circuit itself, a peripheral circuit, and a module can be reduced.

Moreover, when the semiconductor device described in the above embodiment is employed for the portable game machine 5200 or the stationary game machine 7500, it is possible to retain a temporary file necessary for arithmetic operation that occurs during game play.

As an example of a game machine, FIG. 18E illustrates a portable game machine. FIG. 18F illustrates a home-use stationary game machine. Note that the electronic device of one embodiment of the present invention is not limited thereto. Examples of the electronic device of one embodiment of the present invention include an arcade game machine installed in entertainment facilities (a game center, an amusement park, or the like), a throwing machine for batting practice installed in sports facilities, or the like.

### [Moving Vehicle]

The semiconductor device described in the above embodiment can be employed for an automobile, which is a moving vehicle, and around the driver's seat in an automobile.

FIG. 18G illustrates an automobile 5700 as an example of a moving vehicle.

An instrument panel that provides various kinds of information by displaying a speedometer, a tachometer, a mileage, a fuel meter, a gearshift state, air-conditioning settings, and the like is provided around the driver's seat in the automobile 5700. In addition, a display device showing the above information may be provided around the driver's seat.

In particular, the display device can compensate for the view obstructed by a pillar or the like, blind areas for the driver's seat, and the like by displaying a video from an imaging device (not illustrated) provided for the automobile 5700, which can increase safety. That is, display of an image from an imaging device provided on the outside of the automobile 5700 can fill in blind areas and increase safety.

The semiconductor device described in the above embodiment can temporarily retain information. Thus, the semiconductor device can be used to retain temporary information necessary in an automatic driving system for the automobile 5700 or a system for navigation or risk prediction, for example. The display device may be configured to display temporary information regarding navigation, risk prediction, or the like. Moreover, the semiconductor device may be configured to hold a video of a driving recorder provided in the automobile 5700.

Although an automobile is described above as an example of a moving vehicle, the moving vehicle is not limited to an automobile. Examples of moving vehicles include a train, a monorail train, a ship, and a flying object (a helicopter, an unmanned aircraft (drone), an airplane, or a rocket).

### [Camera]

The semiconductor device described in the above embodiment can be employed for a camera.

FIG. 18H illustrates a digital camera 6240 as an example of an imaging device. The digital camera 6240 includes a housing 6241, a display portion 6242, operation switches 6243, a shutter button 6244, and the like, and a detachable lens 6246 is attached to the digital camera 6240. Note that here, although the camera 6240 is configured such that the lens 6246 is detachable from the housing 6241 for replacement, the lens 6246 may be integrated with the housing 6241. In addition, the digital camera 6240 can be additionally equipped with a stroboscope, a viewfinder, or the like.

When the semiconductor device described in the above embodiment is employed for the digital camera 6240, the digital camera 6240 with low power consumption can be achieved. Moreover, heat generation from a circuit can be reduced owing to low power consumption; thus, the influence of heat generation on the circuit itself, a peripheral circuit, and a module can be reduced.

### [Video Camera]

The semiconductor device described in the above embodiment can be employed for a video camera.

FIG. 18I illustrates a video camera 6300 as an example of an imaging device. The video camera 6300 includes a first housing 6301, a second housing 6302, a display portion 6303, operation switches 6304, a lens 6305, a joint 6306, and the like. The operation switches 6304 and the lens 6305 are provided in the first housing 6301, and the display portion 6303 is provided in the second housing 6302. The first housing 6301 and the second housing 6302 are connected to each other with the joint 6306, and an angle between the first housing 6301 and the second housing 6302 can be changed with the joint 6306. Images on the display portion 6303 may be changed in accordance with the angle at the joint 6306 between the first housing 6301 and the second housing 6302.

When images taken by the video camera 6300 are recorded, the images need to be encoded in accordance with a data recording format. With the use of the above semiconductor device, the video camera 6300 can retain a temporary file generated in encoding.

### [ICD]

The semiconductor device described in the above embodiment can be employed for an implantable cardioverter-defibrillator (ICD).

FIG. 18J is a schematic cross-sectional view showing an example of an ICD. An ICD main unit 5400 includes at least a battery 5401, the electronic component 4700, a regulator, a control circuit, an antenna 5404, a wire 5402 reaching a right atrium, and a wire 5403 reaching a right ventricle.

The ICD main unit 5400 is implanted in the body by surgery, and the two wires pass through a subclavian vein 5405 and a superior vena cava 5406 of the human body, with an end of one of the wires placed in the right ventricle and an end of the other wire placed in the right atrium.

The ICD main unit 5400 functions as a pacemaker and paces the heart when the heart rate is not within a predetermined range. In addition, when the heart rate is not recovered by pacing and ventricular tachycardia, ventricular fibrillation, or the like keeps occurring, treatment with an electrical shock is performed.

The ICD main unit 5400 needs to monitor the heart rate all the time in order to perform pacing and deliver electrical shocks as appropriate. For that reason, the ICD main unit 5400 includes a sensor for measuring the heart rate. In addition, in the ICD main unit 5400, data on the heart rate obtained by the sensor or the like, the number of times the treatment with pacing is performed, or the time taken for the treatment, for example, can be stored in the electronic component 4700.

The antenna 5404 can receive power, and the battery 5401 is charged with the power. Furthermore, when the ICD main unit 5400 includes a plurality of batteries, safety can be increased. Specifically, even when one of the batteries in the ICD main unit 5400 is dead, the other batteries can function properly; thus, the batteries also function as an auxiliary power source.

In addition to the antenna 5404 capable of receiving power, an antenna that can transmit physiological signals may be included to construct, for example, a system that monitors cardiac activity by checking a physiological signal such as a pulse, a respiratory rate, a heart rate, or body temperature with an external monitoring device.

### [Expansion Device for PC]

The semiconductor device described in the above embodiment can be employed for a calculator such as a PC (Personal Computer) or an expansion device for an information terminal.

FIG. 19A illustrates, as an example of the expansion device, a portable expansion device 6100 that includes a chip capable of holding information and is externally provided on a PC. The expansion device 6100 can store information using the chip when connected to a PC with a USB (Universal Serial Bus), for example. Note that FIG. 19A illustrates the portable expansion device 6100; however, the expansion device of one embodiment of the present invention is not limited thereto and may be a comparatively large expansion device including a cooling fan, for example.

The expansion device 6100 includes a housing 6101, a cap 6102, a USB connector 6103, and a substrate 6104. The substrate 6104 is held in the housing 6101. The substrate 6104 is provided with a circuit for driving the semiconductor device or the like described in the above embodiment. For example, the substrate 6104 is provided with the electronic component 4700 and a controller chip 6106. The USB connector 6103 functions as an interface for connection to an external device.

### [Sd Card]

The semiconductor device described in the above embodiment can be employed for an SD card that can be attached to an electronic device such as an information terminal or a digital camera.

FIG. 19B is a schematic external view of an SD card, and FIG. 19C is a schematic view of the internal structure of the SD card. An SD card 5110 includes a housing 5111, a connector 5112, and a substrate 5113. The connector 5112 functions as an interface for connection to an external device. The substrate 5113 is held in the housing 5111. The substrate 5113 is provided with a semiconductor device and a circuit for driving the semiconductor device. For example, the substrate 5113 is provided with the electronic components 4700 and a controller chip 5115. Note that the circuit structures of the electronic components 4700 and the controller chip 5115 are not limited to those described above, and can be changed as appropriate according to circumstances. For example, a write circuit, a row driver, a read circuit, or the like that is provided in an electronic component may be incorporated into the controller chip 5115 instead of the electronic component 4700.

When the electronic components 4700 are provided also on a rear surface side of the substrate 5113, the capacitance of the SD card 5110 can be increased. In addition, a wireless chip with a wireless communication function may be provided on the substrate 5113. This allows wireless communication between an external device and the SD card 5110 and enables data reading and writing from and to the electronic components 4700.

### [SSD]

The semiconductor device described in the above embodiment can be employed for an SSD (Solid State Drive) that can be attached to an electronic device such as an information terminal.

FIG. 19D is a schematic external view of an SSD, and FIG. 19E is a schematic view of the internal structure of the SSD. An SSD 5150 includes a housing 5151, a connector 5152, and a substrate 5153. The connector 5152 functions as an interface for connection to an external device. The substrate 5153 is held in the housing 5151. The substrate 5153 is provided with a semiconductor device and a circuit for driving the semiconductor device. For example, the electronic components 4700, a memory chip 5155, and a controller chip 5156 are attached to the substrate 5153. When the electronic components 4700 are also provided on a rear surface side of the substrate 5153, the capacity of the SSD 5150 can be increased. A work memory is incorporated in the memory chip 5155. For example, a DRAM chip is used as the memory chip 5155. A processor, an ECC circuit, or the like is incorporated in the controller chip 5156. Note that the circuit structures of the electronic components 4700, the memory chip 5155, and the controller chip 5115 are not limited to those described above, and the circuit structures can be changed as appropriate according to circumstances. For example, a memory functioning as a work memory may also be provided in the controller chip 5156.

### [Computer]

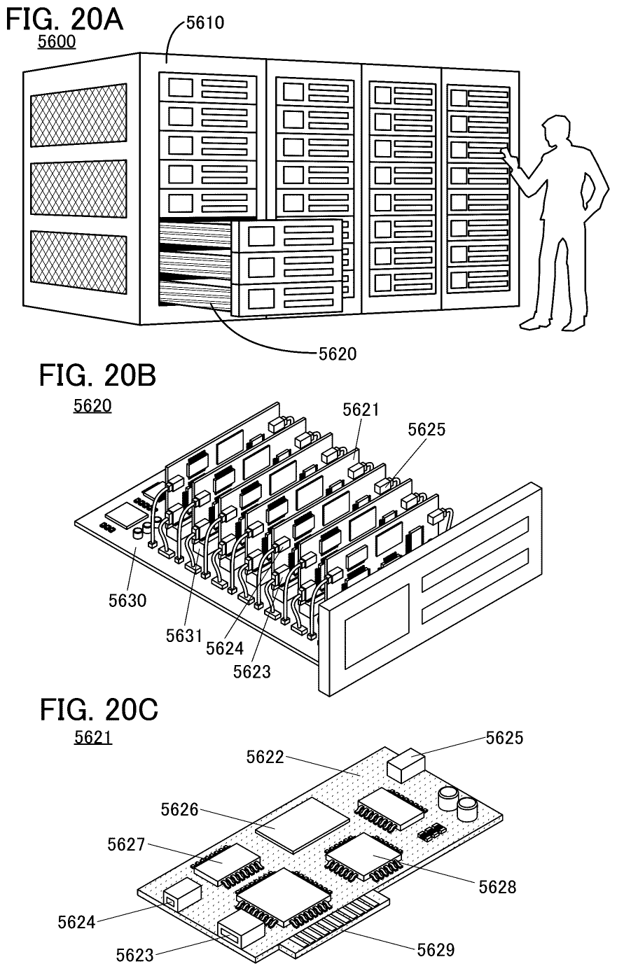

A computer 5600 illustrated in FIG. 20A is an example of a large computer. In the computer 5600, a plurality of rack mount computers 5620 are stored in a rack 5610.

The computer 5620 can have a structure in a perspective view illustrated in FIG. 20B, for example. In FIG. 20B, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 20C is an example of a processing board provided with a CPU, a GPU, a semiconductor device, or the like. The PC card 5621 includes a board 5622. In addition, the board 5622 includes a connection terminal 5623, a connection terminal 5624, a connection terminal 5625, a semiconductor device 5626, a semiconductor device 5627, a semiconductor device 5628, and a connection terminal 5629. Note that FIG. 20C also illustrates semiconductor devices other than the semiconductor device 5626, the semiconductor device 5627, and the semiconductor device 5628, the following description of the semiconductor device 5626, the semiconductor device 5627, and the semiconductor device 5628 is referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can serve as, for example, an interface for performing power supply, or signal input to the PC card 5621. As another example, the connection terminal 5623, the connection terminal 5624, and the connection terminal 5625 can serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In the case where video signals are output from the connection terminal 5623, the connection terminal 5624, and the connection terminal 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA (Field Programmable Gate Array), a GPU, a CPU, and the like. As the semiconductor device 5627, the electronic component 4730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a semiconductor device. As the semiconductor device 5628, the electronic component 4700 can be used, for example.

The computer 5600 can also function as a parallel computer. When the computer 5600 is used as a parallel computer, large-scale computation necessary for artificial intelligence learning and inference can be performed, for example.

When the semiconductor device of one embodiment of the present invention is used in a variety of electronic devices described above, the power consumption of the electronic devices can be reduced.

The structure described in this embodiment can be combined with any of the structures described in the other embodiments as appropriate.

(Notes on Description of this Specification and the Like)

The description of the above embodiments and each structure in the embodiments are noted below.

One embodiment of the present invention can be constituted by combining, as appropriate, the structure described in each embodiment with the structures described in the other embodiments. In addition, in the case where a plurality of structure examples are described in one embodiment, the structure examples can be combined as appropriate.

Content (or may be part of the content) described in one embodiment can be employed for, combined with, or replaced with another content (or may be part of the content) described in the embodiment and/or content (or may be part of the content) described in another embodiment or other embodiments.

In each embodiment, content described in the embodiment is content described using a variety of diagrams or content described with text disclosed in the specification.

When a diagram (or may be part thereof) described in one embodiment is combined with another part of the diagram, a different diagram (or may be part thereof) described in the embodiment, and/or a diagram (or may be part thereof) described in another embodiment or other embodiments, much more diagrams can be formed.

In this specification and the like, components are classified by their functions and illustrated as independent blocks in block diagrams. However, in an actual circuit or the like, it is difficult to divide components according to their functions, and there is such a case where one circuit relates to a plurality of functions or a case where a plurality of circuits relate to one function. Therefore, blocks in the block diagrams are not limited by the components described in this specification, and the description can be changed appropriately depending on the situation.

In the drawings, the size, the layer thickness, or the region is shown with given magnitude for description convenience. Therefore, they are not limited to the illustrated scale. Note that the drawings are schematically shown for clarity, and embodiments of the present invention are not limited to shapes, values or the like shown in the drawings. For example, variation in signal, voltage, or current due to noise, variation in signal, voltage, or current due to difference in timing, or the like can be included.

In this specification and the like, the expressions “one of a source and a drain” (or a first electrode or a first terminal) and “the other of the source and the drain” (or a second electrode or a second terminal), which is for the other of the source and the drain, are used to describe the connection relation of a transistor. This is because the source and the drain of the transistor change depending on the structure, operating conditions, or the like of the transistor. Note that the source or the drain of the transistor can also be referred to as a source (drain) terminal, a source (drain) electrode, or the like as appropriate depending on the situation.

In this specification and the like, the terms “electrode” and “wiring” do not functionally limit these components. For example, an “electrode” is used as part of a “wiring” in some cases, and vice versa. Furthermore, the term “electrode” or “wiring” also includes the case where a plurality of “electrodes” or “wirings” are formed in an integrated manner, for example.

In this specification and the like, voltage and potential can be interchanged with each other as appropriate. The voltage refers to a potential difference from a reference potential, and when the reference potential is a ground voltage, for example, the voltage can be rephrased into the potential. The ground potential does not necessarily mean 0 V. Note that potentials are relative values, and a potential supplied to a wiring or the like is sometimes changed depending on the reference potential, for example.

In this specification and the like, the terms such as “film” and “layer” can be interchanged with each other depending on the case or according to circumstances. For example, the term “conductive layer” can be changed into the term “conductive film” in some cases. As another example, the term “insulating film” can be changed into the term “insulating layer” in some cases.

In this specification and the like, a switch has a function of controlling whether current flows or not by being in a conduction state (an on state) or a non-conduction state (an off state). Alternatively, a switch has a function of selecting and changing a current path.

In this specification and the like, channel length refers to, for example, the distance between a source and a drain in a region where a semiconductor (or a portion where current flows in a semiconductor when a transistor is in an on state) and a gate overlap with each other or a region where a channel is formed in a top view of the transistor.

In this specification and the like, channel width refers to, for example, the length of a portion where a source and a drain face each other in a region where a semiconductor (or a portion where current flows in a semiconductor when a transistor is in an on state) and a gate electrode overlap with each other or a region where a channel is formed.

In this specification and the like, when A and B are connected, it means the case where A and B are electrically connected to each other as well as the case where A and B are directly connected to each other. Here, when A and B are electrically connected, it means the case where electric signals can be sent and received between A and B when an object having any electric action exists between A and B.

### REFERENCE NUMERALS

BL: wiring, FE: ferroelectric layer, LE: electrode, MC: memory cell, M1: transistor, PL: wiring, UE: electrode, WL: wiring

1. A semiconductor device comprising:
a first transistor;
a second transistor;
a first capacitor;
a second capacitor; and
a wiring,
wherein the first transistor is electrically connected to the first capacitor,
wherein the second transistor is electrically connected to the second capacitor,
wherein the wiring is positioned below the first transistor and the second transistor and is electrically connected to the first transistor or the second transistor,
wherein the wiring is positioned between a gate electrode of the first transistor and a gate electrode of the second transistor in a plan view,
wherein the first capacitor and the second capacitor each comprise a ferroelectric layer, and
wherein the first capacitor and the second capacitor are placed on the same plane.

2. A semiconductor device comprising:
a first transistor;
a second transistor;
a first capacitor;
a second capacitor; and
a wiring,
wherein the first transistor is electrically connected to the first capacitor,
wherein the second transistor is electrically connected to the second capacitor,
wherein the wiring is positioned below the first transistor and the second transistor and is electrically connected to the first transistor or the second transistor,
wherein the wiring is positioned between a gate electrode of the first transistor and a gate electrode of the second transistor in a plan view,
wherein the first capacitor and the second capacitor each comprise a ferroelectric layer, and
wherein the first capacitor and the second capacitor comprise a region where they overlap with each other.

3. The semiconductor device according to claim 1,
wherein each of the first transistor and the second transistor comprises an oxide semiconductor in a channel.

4. The semiconductor device according to claim 1,
wherein the ferroelectric layer comprises one or more selected from hafnium, zirconium, and Group 13 to Group 15 elements.

5. An electronic device comprising:
the semiconductor device according to claim 1; and
a CPU.

6. The semiconductor device according to claim 1,
wherein the first transistor and the second transistor comprise an oxide semiconductor overlapping with the wiring.

7. The semiconductor device according to claim 2,
wherein each of the first transistor and the second transistor comprises an oxide semiconductor in a channel.

8. The semiconductor device according to claim 2,
wherein the ferroelectric layer comprises one or more selected from hafnium, zirconium, and Group 13 to Group 15 elements.

9. An electronic device comprising:
the semiconductor device according to claim 2; and
a CPU.

10. The semiconductor device according to claim 2,
wherein the first transistor and the second transistor comprise an oxide semiconductor overlapping with the wiring.
